(19) United States
(12) Patent Application Publication
(10) Pub. No.: US 2024/0321630 A1
(43) Pub. Date: Sep. 26, 2024

(54) TOP VIA INTERCONNECT

(71) Applicant: INTERNATIONAL BUSINESS MACHINES CORPORATION, ARMONK, NY (US)

(72) Inventors: Ruilong Xie, Niskayuna, NY (US); Christopher J. Waskiewicz, Rexford, NY (US); Chih-Chao Yang, Glenmont, NY (US); Huai Huang, Clifton Park, NY (US); Koichi Motoyama, Clifton Park, NY (US); Julien Frougier, Albany, NY (US)

(21) Appl. No.: 18/187,738

(22) Filed: Mar. 22, 2023

(51) Int. Cl. H01L 21/768; H01L 23/522; H01L 23/532

(52) U.S. Cl. CPC H01L 21/7682; H01L 21/76802; H01L 21/76834; H01L 21/76877; H01L 21/76897; H01L 23/5226; H01L 23/53252

(57) ABSTRACT

A semiconductor structure including first metal lines embedded in a first dielectric layer, second metal lines embedded in a second dielectric layer, where the second metal lines arranged above the first metal lines, a top via extending between one of the first metal lines and one of the second metal lines, where the top via is self-aligned to the one of the first metal lines, and at least one air gap located adjacent to the top via between the first metal lines and the second metal lines.

### BACKGROUND

The present invention generally relates to semiconductor structures, and more particularly to back end of line interconnect structures with self-aligned top via interconnects.

Integrated circuit processing can be generally divided into front end of the line (FEOL), middle of the line (MOL) and back end of the line (BEOL) processes. The FEOL and MOL processing will generally form many layers of logical and functional devices. By way of example, the typical FEOL processes include wafer preparation, isolation, well formation, gate patterning, spacer, extension and source/drain implantation, silicide formation, and dual stress liner formation. The MOL is mainly gate contact formation. Layers of interconnections are formed above these logical and functional layers during the BEOL processing to complete the integrated circuit structure. As such, BEOL processing generally involves the formation of insulators and conductive wiring. The industry has typically used copper as the conductive metal for the interconnect structures most often using a dual damascene process to form a metal line/via interconnect structure.

As integrated circuits continue to reduce in size, implementing effective isolation of working components in these devices becomes more difficult. In the case of transistor structures in particular, design requirements call for effective isolation of working components to reduce negative effects such as parasitic capacitive coupling and undesirably high power consumption.

### SUMMARY

According to an embodiment of the present invention, a semiconductor structure is provided. The semiconductor structure may include first metal lines embedded in a first dielectric layer, second metal lines embedded in a second dielectric layer, where the second metal lines are arranged above the first metal lines, a top via extending between one of the first metal lines and one of the second metal lines, where the top via is self-aligned to the one of the first metal lines, and at least one air gap located adjacent to the top via between the first metal lines and the second metal lines.

According to an embodiment of the present invention the semiconductor structure further includes a dielectric liner surrounding sides and a bottom of the at least one air gap.

According to an embodiment of the present invention the dielectric liner directly contacts all topmost surfaces of the first metal lines directly beneath the second metal lines except where the top via is positioned.

According to an embodiment of the present invention the semiconductor structure further includes masks above and directly contacting topmost surfaces of the first metal lines except where the first metal lines are directly beneath the second metal lines, wherein bottom most surfaces of the masks are substantially flush with a bottom most surface of the top via.

According to an embodiment of the present invention a bottom most surface of the second metal lines is below a topmost surface of the first dielectric layer.

According to an embodiment of the present invention the first metal lines directly contact the first dielectric layer without a barrier liner, wherein the top via directly contacts the first dielectric layer without a barrier liner, and wherein the second metal lines directly contact both the first dielectric layer and the second dielectric layer without a barrier liner.

According to an embodiment of the present invention the first metal lines and the second metal lines comprise ruthenium.

According to another embodiment of the present invention, a semiconductor structure is provided. The semiconductor structure may include first metal lines embedded in a first dielectric layer, second metal lines embedded in a second dielectric layer, wherein the second metal lines are arranged above the first metal lines, a top via extending between one of the first metal lines and one of the second metal lines, wherein the top via is self-aligned to the one of the first metal lines, and at least one air gap located adjacent to the top via between the first metal lines and the second metal lines, wherein the at least one air gap is in the same level as the top via.

According to an embodiment of the present invention the semiconductor structure further includes a dielectric liner surrounding sides and a bottom of the at least one air gap.

According to an embodiment of the present invention the dielectric liner directly contacts all topmost surfaces of the first metal lines directly beneath the second metal lines except where the top via is positioned.

According to an embodiment of the present invention the semiconductor structure further includes masks above and directly contacting topmost surfaces of the first metal lines except where the first metal lines are directly beneath the second metal lines, wherein bottom most surfaces of the masks are substantially flush with a bottom most surface of the top via.

According to an embodiment of the present invention a bottom most surface of the second metal lines is below a topmost surface of the first dielectric layer.

According to an embodiment of the present invention wherein the first metal lines directly contact the first dielectric layer without a barrier liner, wherein the top via directly contacts the first dielectric layer without a barrier liner, and wherein the second metal lines directly contact both the first dielectric layer and the second dielectric layer without a barrier liner.

According to an embodiment of the present invention wherein the first metal lines and the second metal lines comprise ruthenium.

According to another embodiment of the present invention, a semiconductor structure is provided. The semiconductor structure may include first metal lines embedded in a first dielectric layer, second metal lines embedded in a second dielectric layer, wherein the second metal lines are arranged above the first metal lines, a top via extending between one of the first metal lines and one of the second metal lines, wherein the top via is self-aligned to the one of the first metal lines, and at least one air gap located in the same level as the top via, wherein the at least one air gap is arranged at intersections between the first metal lines and the second metal lines.

According to an embodiment of the present invention the semiconductor structure further includes a dielectric liner surrounding sides and a bottom of the at least one air gap.

According to an embodiment of the present invention the dielectric liner directly contacts all topmost surfaces of the first metal lines directly beneath the second metal lines except where the top via is positioned.

According to an embodiment of the present invention the semiconductor structure further includes masks above and directly contacting topmost surfaces of the first metal lines except where the first metal lines are directly beneath the second metal lines, wherein bottom most surfaces of the masks are substantially flush with a bottom most surface of the top via.

According to an embodiment of the present invention a bottom most surface of the second metal lines is below a topmost surface of the first dielectric layer.

According to an embodiment of the present invention the first metal lines directly contact the first dielectric layer without a barrier liner, wherein the top via directly contacts the first dielectric layer without a barrier liner, and wherein the second metal lines directly contact both the first dielectric layer and the second dielectric layer without a barrier liner.

According to an embodiment of the present invention the first metal lines and the second metal lines comprise ruthenium.

According to another embodiment of the present invention, a semiconductor structure is provided. The semiconductor structure may include first metal lines embedded in a first dielectric layer, second metal lines embedded in a second dielectric layer, wherein the second metal lines are arranged above the first metal lines, a top via extending between one of the first metal lines and one of the second metal lines, wherein the top via is self-aligned to the one of the first metal lines, at least one air gap located in the same level as the top via, wherein the at least one air gap is arranged at intersections between the first metal lines and the second metal lines, a dielectric liner surrounding sides and a bottom of the at least one air gap, and masks above and directly contacting topmost surfaces of the first metal lines except where the first metal lines are directly beneath the second metal lines, wherein bottom most surfaces of the masks are substantially flush with a bottom most surface of the top via.

According to an embodiment of the present invention the dielectric liner directly contacts all topmost surfaces of the first metal lines directly beneath the second metal lines except where the top via is positioned.

According to an embodiment of the present invention, a semiconductor structure is provided. The semiconductor structure may include first metal lines embedded in a first dielectric layer, second metal lines embedded in a second dielectric layer, wherein the second metal lines are arranged above the first metal lines, a top via extending between one of the first metal lines and one of the second metal lines, wherein the top via is self-aligned to the one of the first metal lines, dielectric plugs located in the same level as the top via and directly above all of the first metal lines except where the top via is positioned, and at least one air gap located within at least one of the dielectric plugs separating it from both the first dielectric layer and the second dielectric layer.

According to an embodiment of the present invention each of the dielectric plugs is self-aligned with each of the first metal lines, respectively.

### BRIEF DESCRIPTION OF THE DRAWINGS

The following detailed description, given by way of example and not intended to limit the invention solely thereto, will best be appreciated in conjunction with the accompanying drawings, in which:

FIG. 1 is a cross-sectional view of a first semiconductor structure during an intermediate step of a method of fabricating an interconnect structure according to an exemplary embodiment;

FIG. 2 is a cross-sectional view of the first semiconductor structure after patterning openings in the first metal layer and exposing the underlying level according to an exemplary embodiment;

FIG. 3 is a cross-sectional view of the first semiconductor structure after forming a first dielectric layer according to an exemplary embodiment;

FIG. 4 is a cross-sectional view of the first semiconductor structure after an etch stop layer, a second dielectric layer, and a sacrificial mask according to an exemplary embodiment;

FIG. 5 is a cross-sectional view of the first semiconductor structure after removing a portion of the etch stop layer according to an exemplary embodiment;

FIG. 6 is a cross-sectional view of the first semiconductor structure after forming a planarization layer and a second hard mask layer according to an exemplary embodiment;

FIG. 7 is a cross-sectional view of the first semiconductor structure after removing the single individual mask exposed at the bottom of the opening and removing the second hard mask layer according to an exemplary embodiment;

FIG. 8 is a cross-sectional view of the first semiconductor structure after removing the planarization layer and forming self-aligned top vias according to an exemplary embodiment;

FIG. 9 is a cross-sectional view of the first semiconductor structure after removing additional individual masks exposed in the trenches according to an exemplary embodiment;

FIG. 10 is a cross-sectional view of the first semiconductor structure after forming a liner and a third dielectric layer according to an exemplary embodiment;

FIG. 11 is a cross-sectional view of the first semiconductor structure after recessing the third dielectric layer according to an exemplary embodiment;

FIG. 12 is a cross-sectional view of the first semiconductor structure after recessing the liner according to an exemplary embodiment;

FIGS. 13, 14, and 15 are cross-sectional views of the first semiconductor structure after forming second metal lines according to an exemplary embodiment;

FIG. 16 is a cross-sectional view of a second semiconductor structure during an intermediate step of a method of fabricating an interconnect structure according to an exemplary embodiment;

FIG. 17 is a cross-sectional view of the second semiconductor structure after patterning openings in the first metal layer and exposing the underlying level according to an exemplary embodiment;

FIG. 18 is a cross-sectional view of the second semiconductor structure after forming a first dielectric layer according to an exemplary embodiment;

FIG. 19 is a cross-sectional view of the second semiconductor structure after forming a planarization layer and a second hard mask layer according to an exemplary embodiment;

FIG. 20 is a cross-sectional view of the second semiconductor structure after removing the single individual mask exposed at the bottom of the opening and removing the second hard mask layer according to an exemplary embodiment;

FIG. 21 is a cross-sectional view of the second semiconductor structure after forming self-aligned top vias, and removing the planarization layer according to an exemplary embodiment;

FIG. 22 is a cross-sectional view of the second semiconductor structure after removing remaining individual masks according to an exemplary embodiment;

FIG. 23 is a cross-sectional view of the second semiconductor structure after forming a second dielectric layer according to an exemplary embodiment; and

FIGS. 24, 25, and 26 are cross-sectional views of the second semiconductor structure after forming second metal lines and a third dielectric layer according to an exemplary embodiment.

The drawings are not necessarily to scale. The drawings are merely schematic representations, not intended to portray specific parameters of the invention. For clarity and ease of illustration, scale of elements may be exaggerated. The drawings are intended to depict only typical embodiments of the invention. In the drawings, like numbering represents like elements.

Additionally, XYZ Cartesian coordinates may be also shown in each of the drawings to provide additional spatial context. The terms “vertical” or “vertical direction” or “vertical height” as used herein denote a Z-direction of the Cartesian coordinates shown in the drawings, and the terms “horizontal,” or “horizontal direction,” or “lateral direction” as used herein denote an X-direction and/or a Y-direction of the Cartesian coordinates shown in the drawings.

### DETAILED DESCRIPTION

Detailed embodiments of the claimed structures and methods are disclosed herein; however, it can be understood that the disclosed embodiments are merely illustrative of the claimed structures and methods that may be embodied in various forms. This invention may, however, be embodied in many different forms and should not be construed as limited to the exemplary embodiments set forth herein. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, the terms “upper”, “lower”, “right”, “left”, “vertical”, “horizontal”, “top”, “bottom”, and derivatives thereof shall relate to the disclosed structures and methods, as oriented in the drawing figures. It will be understood that when an element as a layer, region or substrate is referred to as being “on” or “over” another element, it can be directly on the other element or intervening elements may also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Also, the term “sub-lithographic” may refer to a dimension or size less than current dimensions achievable by photolithographic processes, and the term “lithographic” may refer to a dimension or size equal to or greater than current dimensions achievable by photolithographic processes. The sub-lithographic and lithographic dimensions may be determined by a person of ordinary skill in the art at the time the application is filed.

The terms substantially, substantially similar, about, or any other term denoting functionally equivalent similarities refer to instances in which the difference in length, height, or orientation convey no practical difference between the definite recitation (e.g. the phrase sans the substantially similar term), and the substantially similar variations. In one embodiment, substantial (and its derivatives) denote a difference by a generally accepted engineering or manufacturing tolerance for similar devices, up to, for example, 10% deviation in value or 10° deviation in angle.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

As the pitch of BEOL metal features decreases, the metal lines themselves get narrower and narrower making it increasingly more difficult to maintain adequate isolation and insulation between adjacent metal features. Subtractive metal patterning schemes, such as top via schemes, have become an attractive solution for producing narrow metal features having relatively tight pitch because no metal liner is needed allowing for a larger volume conductor and thereby lowering resistance. One drawback to a subtractive top via scheme is that it remains difficult to form a subtractive “top via” which is also self-aligned to the metal level immediately above. This is especially true when top metal lines have a relatively relaxed pitch and can be formed with conventional damascene process. Finally, it is very desirable to have the top via scheme be compatible with fully aligned vias.

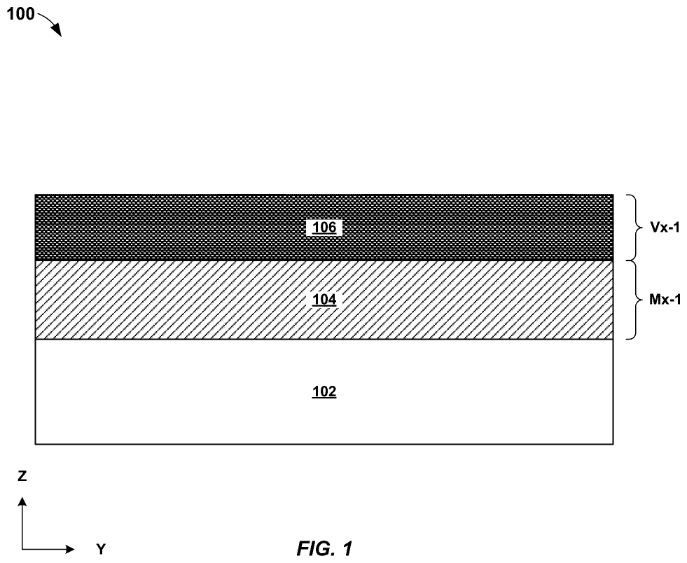

The present invention generally relates to semiconductor structures, and more particularly to back end of line interconnect structures with self-aligned top via interconnects. More specifically, the interconnect structures and associated method disclosed herein enable a novel solution for reducing capacitance between leftover masking materials and the metal level formed immediately above the top via interconnect structures. According to embodiments of the present invention, the top via scheme disclosed herein refers to a subtractivly formed metal level having a self-aligned via subsequently formed thereon. Exemplary embodiments of the interconnect structures are described in detail below by referring to the accompanying drawings in FIGS. 1 to 26. Those skilled in the art will readily appreciate that the detailed description given herein with respect to these figures is for explanatory purposes as the invention extends beyond these limited embodiments.

Referring now to FIG. 1, a demonstrative illustration of a first structure 100 (hereinafter structure 100) is shown during an intermediate step of a method of fabricating an interconnect structure according to an embodiment of the invention. More specifically, as disclosed herein, the method may begin with an underlying level 102 having a first metal layer 104 and a first hard mask layer 106 formed thereon.

For purposes of the present description, the underlying level 102 represents any one of a front-end-of-line device layer, a middle-of-line metal layer, or a back-end-of-line metal layer. In at least one example, the underlying level 102 may include one or more contacts or contact vias present in a front-end-of-line device layer or a back-end-of-line metal layer. In yet another example, the underlying level 102 may include one or more metal lines, via or other conductors present in a middle-of-line metal layer or a back-end-of-line metal layer.

The first metal layer 104 of the present embodiment is formed directly on top of the underlying level 102 according to known techniques. The first metal layer 104 can include any suitable interconnect metal which may be easily removed by a subtractive etch. For example, the first metal layer 104 can include aluminum, copper, ruthenium, cobalt, rhodium, iridium, nickel, or alloys thereof or the like as desired for the application. In at least one embodiment, the first metal layer 104 is made from ruthenium for low electrical resistance and high resistance to electromigration. The first metal layer 104 can be deposited using known techniques, such as, for example, CVD, sputtering, electrochemical deposition or like processes. In an embodiment, the thickness of the first metal layer 104 can range from approximately 20 nm to approximately 100 nm; however, other thicknesses lesser than 20 nm and greater than 100 nm are explicitly contemplated. In some embodiments, an adhesion layer (not shown) is provided between the underlying level 102 and the first metal layer 104; however, such is not necessary. In such cases, the adhesion layer may be a relatively thin layer of titanium nitride.

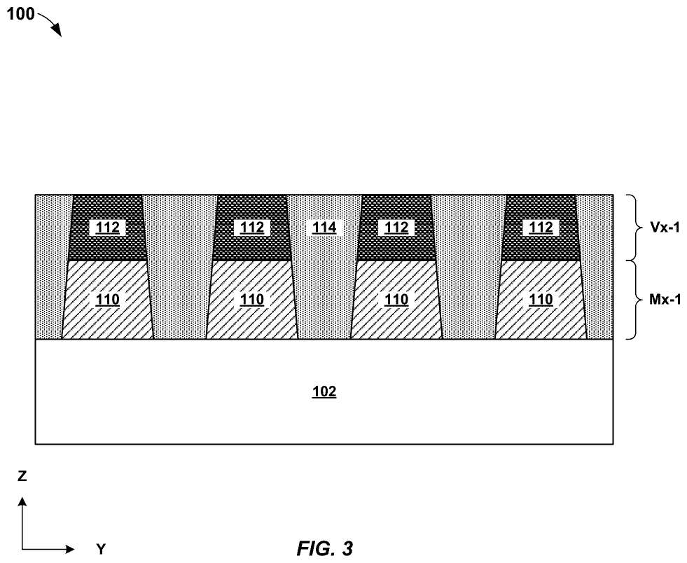

Finally, the first hard mask layer 106 of the present embodiment is formed directly on top of the first conductive layer 104 as illustrated and according to known techniques. The first hard mask layer 106 can include any known dielectric hard mask materials suitable for facilitating subsequent patterning and etching techniques. In all cases, the first hard mask layer 106 is preferably made from a dielectric material which is capable of being etched or patterned selective to a first dielectric layer (FIG. 3) and the metal lines (110). For example, the first hard mask layer 106 can include nitrides, such as, silicon nitride, titanium nitride, tantalum nitride, aluminum nitride, or silicon carbon nitride. In at least one embodiment, for example, the first hard mask layer 106 is a layer of silicon nitride. In another embodiment, the first hard mask layer 106 is a layer of silicon carbon nitride. Finally, the first hard mask layer 106 is sacrificial in nature because some or all of it will be removed during subsequent processes and will no longer be present in the final structure. The first hard mask layer 106 can be formed by any deposition technique including, for example, chemical vapor deposition (CVD), plasma enhanced chemical vapor deposition (PECVD), physical vapor deposition (PVD), sputtering, or atomic layer deposition.

The cumulative thickness of the first metal layer 104 and the first hard mask layer 106 is approximately equal to a desired thickness of a typical metallization level formed on, and subsequent to, the underlying level 102. Specifically, the relative thickness of the first metal layer 104 corresponds to a desired height or thickness of a typical metal level (eg Mx−1) and the relative thickness of the first hard mask layer 106 corresponds to a desired height or thickness of a typical via level (eg Vx−1). In some embodiments, the thickness of the first hard mask layer 106 is substantially equal to the thickness of the first metal layer 104. In other embodiments, the first hard mask layer 106 can be thicker than the first metal layer 104. In yet other embodiments, the first hard mask layer 106 can be thinner than the first metal layer 104. It is noted, a final height of subsequently formed metal lines and top vias are not solely dependent on the relative height or thickness of either the first metal layer 104 or the first hard mask layer 106, respectively.

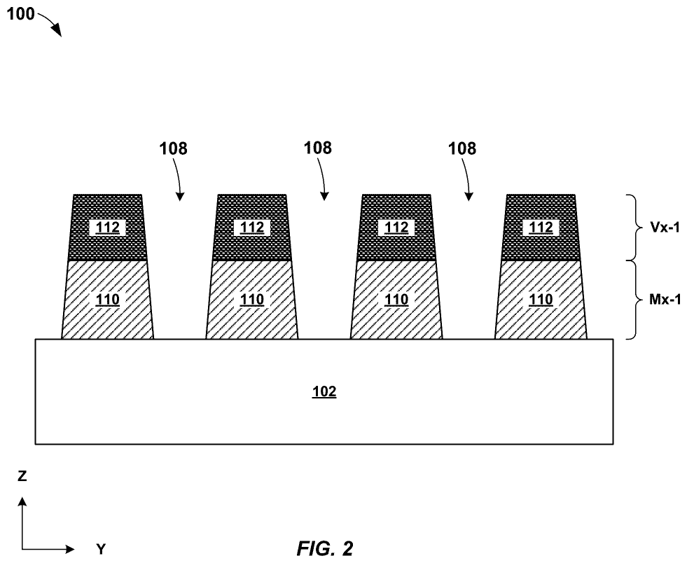

Referring now to FIG. 2, the structure 100 is shown after patterning openings 108 in the first metal layer 104 and exposing the underlying level 102 according to an embodiment of the invention.

The openings 108 of the present embodiment are patterned in the structure 100 according to known techniques. The openings 108 may be patterned by applying a photoresist (not shown), and exposing the photoresist to a desired pattern of radiation and developing the exposed photoresist utilizing a conventional resist developer. The pattern in the photoresist may then be transferred to the first hard mask layer 106 and the first metal layer 104 according to known techniques. For example, one or more suitable etching techniques such as dry etch, wet etch, or combination of both may be used to pattern the openings 108.

After patterning, remaining portions of the first hard mask layer 106 become a plurality of individual masks 112, and remaining portions of the first metal layer 104 become first metal lines 110, as illustrated. The first metal lines 110 formed according to the processes described herein are formed according to conventional subtractive techniques.

In general, the openings 108, and similarly the first metal lines 110, may be spaced apart according to lithography limitations, ground rules, or both. In some embodiments, the openings 108 are spaced equal distances apart; however, doing so is not required. Finally, only three openings 108 are shown in FIG. 2 for illustrative purposes only. As is well known by persons having ordinary skill in the art, any typical semiconductor structure will have multiple back-end-of-line interconnect structures, the structure 100 of the present invention also explicitly includes multiple openings 108 despite not being shown in the figures.

Referring now to FIG. 3, the structure 100 is shown after forming a first dielectric layer 114 according to an embodiment of the invention.

The first dielectric layer 114 of the present embodiment is blanket deposited on top of the structure 100, and more specifically filling the openings 108 as illustrated and according to known techniques. As such, the first metal lines 110 become embedded in the first dielectric layer 114.

The first dielectric layer 114 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-κ dielectrics, porous dielectrics, or some combination thereof. The term “low-κ” as used herein refers to a material having a relative dielectric constant k which is lower than that of silicon dioxide. In an embodiment, the first dielectric layer 114 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

For example, in an embodiment, the first dielectric layer 114 is made from hydrogenated silicon carbon oxide (SiCOH). In another embodiment, the first dielectric layer 114 is made from carbon rich silicon carbon nitride (SiCN). In all cases, the first dielectric layer 114 should be formed of a dielectric material that has adequate etch selectivity with respect to surrounding dielectric, for example the individual masks 112, as well as other subsequently formed materials as discussed below.

Finally, a chemical mechanical polishing technique is used to remove excess unwanted dielectric material from upper surfaces of the structure 100. As a result, topmost surfaces of the first dielectric layer 114 will be flush, or substantially flush with topmost surfaces of the individual masks 112.

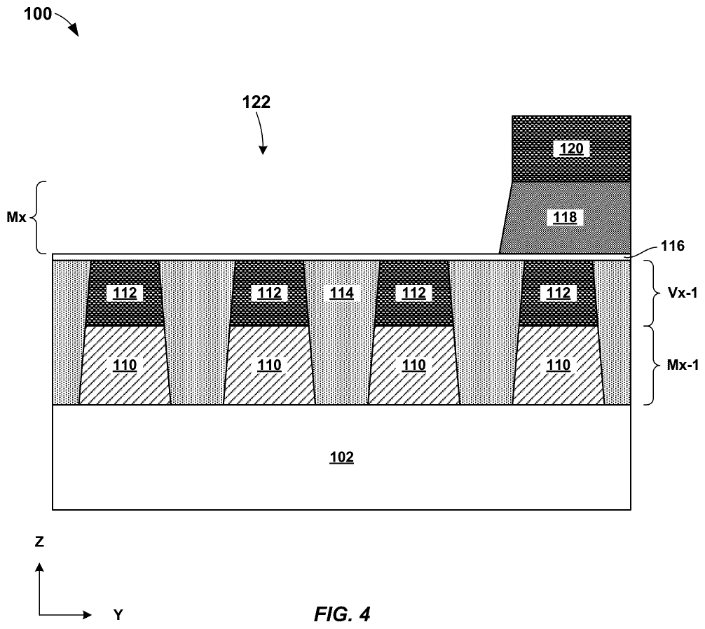

Referring now to FIG. 4, the structure 100 is shown after forming an etch stop layer 116, a second dielectric layer 118, and a sacrificial mask 120 according to an embodiment of the invention.

The etch stop layer 116 of the present embodiment is blanket deposited on top of the structure 100 as illustrated and according to known techniques. Specifically, the etch stop layer 116 covers exposed portions of the individual masks 112 and the first dielectric layer 114. The etch stop layer 116 can include any known etch stop material. In the present embodiment, the etch stop layer 104 must protect the individual masks 112 and the first dielectric layer 114 during subsequent processing. For example, the etch stop layer 116 may be made from aluminum nitride. In an embodiment, the thickness of the etch stop layer 116 can range from approximately 1 nm to approximately 10 nm; however, other thicknesses greater than 10 nm are explicitly contemplated.

Next, the second dielectric layer 118 of the present embodiment is blanket deposited on top of the structure 100 as illustrated and according to known techniques. Like the first dielectric layer 114, the second dielectric layer 118 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-κ dielectrics, porous dielectrics, or some combination thereof. In an embodiment, the second dielectric layer 118 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

For example, in an embodiment, the second dielectric layer 118 is made from hydrogenated silicon carbon oxide (SiCOH). In another embodiment, the second dielectric layer 118 is made from carbon rich silicon carbon nitride (SiCN). In all cases, the second dielectric layer 118 should be formed of a dielectric material that is suitable for subsequent damascene processing. According to at least one embodiment, the second dielectric layer 118 is made from an identical dielectric material as the first dielectric layer 114. In at least another embodiment, the second dielectric layer 118 is made from a different material than the first dielectric layer 114.

The relative thickness of the second dielectric layer 118 is approximately equal to a desired thickness of a typical metallization level formed on, and subsequent to, the underlying Mx−1 and Vx−1 levels. Specifically, the relative thickness of the second dielectric layer 118 corresponds to a desired height or thickness of a typical metal level (eg Mx).

Next, a sacrificial masking layer (not shown) is formed directly on top of the second dielectric layer 118 as illustrated and according to known techniques. The sacrificial masking layer can include any known dielectric hard mask materials suitable for facilitating subsequent patterning and etching techniques. For example, the sacrificial masking layer can include nitrides, such as, silicon nitride, titanium nitride, tantalum nitride, aluminum nitride, or silicon carbon nitride. In at least one embodiment, for example, the sacrificial masking layer is a relatively thin layer of silicon nitride. In another embodiment, the sacrificial masking layer is a relatively thin layer of silicon carbon nitride. Finally, the sacrificial masking layer is sacrificial in nature because it will be removed during subsequent processes and will no longer be present in the final structure.

Finally, trenches 122 are patterned in the structure 100 as illustrated and according to known techniques. Despite only a single trench being depicted in FIG. 4, embodiments of the present invention explicitly contemplate patterning multiple trenches. The trenches 122 may be patterned by applying a photoresist (not shown), and exposing the photoresist to a desired pattern of radiation and developing the exposed photoresist utilizing a conventional resist developer. The pattern in the photoresist may then be transferred to the sacrificial masking layer and second dielectric layer 118 according to known techniques. For example, one or more suitable etching techniques such as dry etch, wet etch, or combination of both may be used to pattern the trenches 122. In all cases, patterning or etching is designed to stop on the etch stop layer 116. Said differently, the etch stop layer 116 protects the underlying materials during etching of the trenches 122. After patterning, remaining portions of the sacrificial masking layer become the sacrificial mask 120.

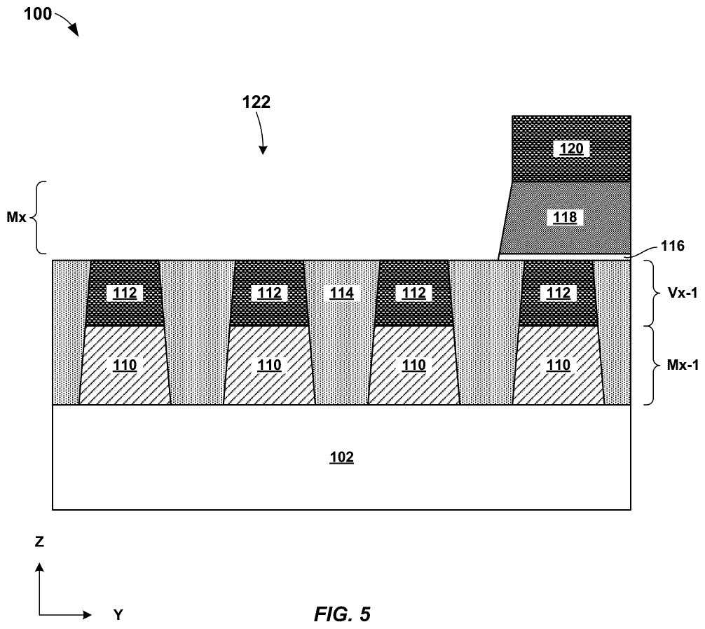

Referring now to FIG. 5, the structure 100 is shown after removing a portion of the etch stop layer 116 according to an embodiment of the invention.

Using the same pattern created during forming the trenches 122, exposed portions of the etch stop layer 116 are removed as illustrated and according to known techniques. Exposed portions of the etch stop layer 116 are removed selective to the sacrificial mask 120 and remaining portions of the second dielectric layer 118. Stated differently the etch stop layer 116 is removed from a bottom of the trenches 122, as illustrated. After which, portions of the etch stop layer 116 beneath the second dielectric layer 118 remain.

One or more suitable etching techniques may be applied to etch exposed portions of the etch stop layer 116. Suitable dry etching techniques may include, but are not limited to: reactive ion etching (RIE), ion beam etching, plasma etching, or laser ablation. Such etching techniques should be designed to remove portions of the etch stop layer 116 selective the sacrificial mask 120 and remaining portions of the second dielectric layer 118.

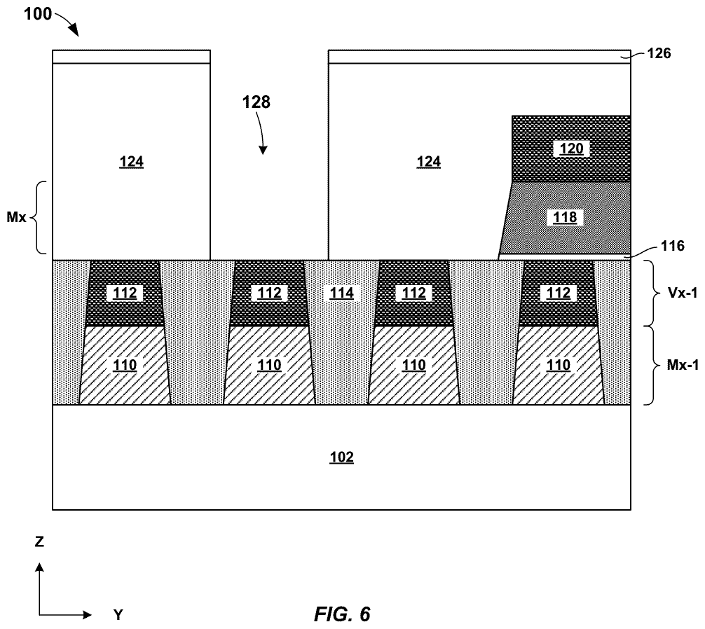

Referring now to FIG. 6, the structure 100 is shown after forming a planarization layer 124 and a second hard mask layer 126 in accordance with an embodiment of the present invention.

The planarization layer 124 of the present embodiment is blanket deposited directly on exposed surfaces of the structure 100 and filling the trenches 122 (FIG. 5) as illustrated and according to known techniques. The planarization layer 124 can be an organic planarization layer or a layer of material that is capable of being planarized or etched by known techniques. In an embodiment, for example, the planarization layer 124 can be an amorphous carbon layer able to withstand the high temperatures of subsequent processing steps. The planarization layer 124 can preferably have a thickness sufficient to cover existing structures. For example, the planarization layer 124 would typically be deposited such that is covers both the second dielectric layer 118 and the sacrificial mask 120.

Next, the second hard mask layer 126 of the present embodiment is deposited directly on the planarization layer 124 as illustrated and according to known techniques. The second hard mask layer 126 can include any known hard mask materials suitable for facilitating subsequent patterning and etching techniques. In all cases, the second hard mask layer 126 is preferably made from a material which is capable of being etched or patterned selective to the planarization layer 124 and other surrounding metal features. The second hard mask layer 126 can include known antireflective coatings, such as, SiARC, TiARC, TiOx, LTO, SiON, etc. Finally, the second hard mask layer 126 is sacrificial in nature because it will be removed during subsequent processes and will no longer be present in the final structure. The second hard mask layer 126 can be formed by any deposition technique including, for example, chemical vapor deposition (CVD), plasma enhanced chemical vapor deposition (PECVD), physical vapor deposition (PVD), sputtering, or atomic layer deposition. Finally, the second hard mask layer 126 and the planarization layer 124, both of the present embodiment, are patterned to create an opening 128 as illustrated and according to known techniques. The opening 128 is arranged to expose a single individual mask 112, as illustrated. Similarly, the opening 128 is arrange directly above a single first metal line 110, also as illustrated.

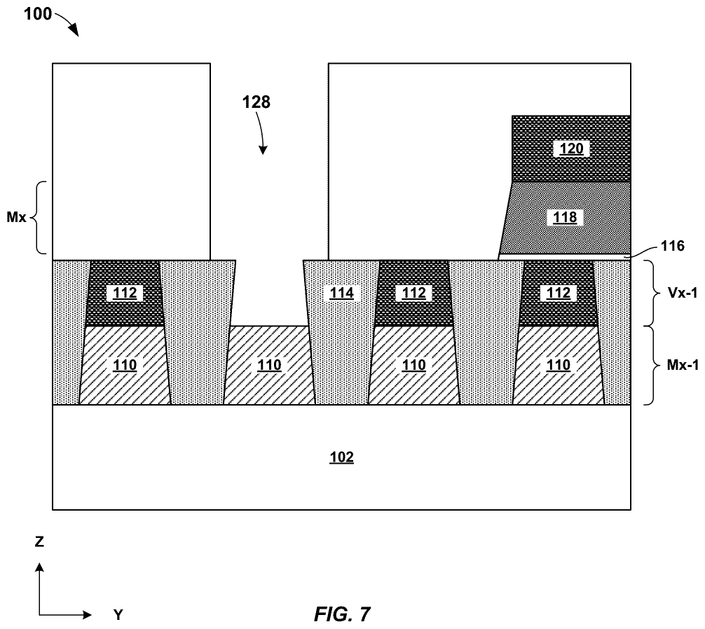

Referring now to FIG. 7, the structure 100 is shown after removing the single individual mask 112 exposed at the bottom of the opening 128 and removing the second hard mask layer 126 according to an embodiment of the invention.

The single individual mask 112 exposed at the bottom of the opening 128 and the second hard mask layer 126 are removed selective to the underlying structures as illustrated and according to known techniques. For example, in at least one embodiment, the single individual mask 112 is removed selective to the first dielectric layer 114 and the first metal lines 110, and the second hard mask layer 126 is removed selective to the planarization layer 124. One or more suitable etching techniques such as dry etch, wet etch, or combination of both may be used to remove the single individual mask 112 and the second hard mask layer 126. For example, suitable dry etching techniques may include, but are not limited to: reactive ion etching (RIE), ion beam etching, plasma etching, or laser ablation. The primary purpose of this etch is to remove the single individual mask 112, and removal of the second hard mask layer 126 is a consequence when similar hard mask materials are used. Embodiments of the present invention explicitly contemplate the single individual mask 112 and the second hard mask layer 126 being different hard mask materials thus requiring an additional etching step to remove the second hard mask layer 126, despite doing so being less efficient.

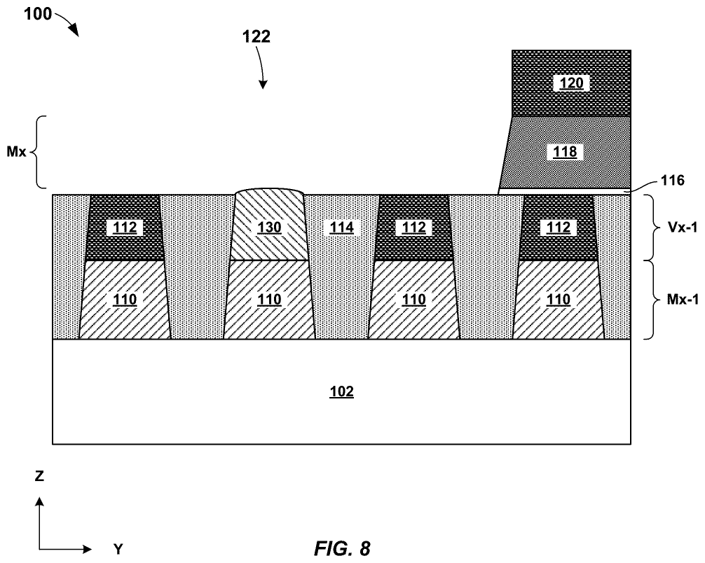

Referring now to FIG. 8, the structure 100 is shown after removing the planarization layer 124 and forming self-aligned top vias 130 according to an embodiment of the invention.

First, the planarization layer 124 is removed selective to all underlying structures as illustrated and according to known techniques. For example, in at least one embodiment, the planarization layer 124 is removed by ashing.

Next, the self-aligned top vias 130 (hereinafter top vias 130) of the present embodiment are formed directly on top of the single first metal line 110 as illustrated and according to known techniques. Specifically, the void created by removing the single individual mask 112 exposed at the bottom of the opening 128 (FIG. 7) is filled with a conductive material to form the top vias 130. For example, known CVD or ALD techniques may be used to selectively deposit the metals, such as, for example, tungsten, ruthenium, aluminum, copper, ruthenium, cobalt, rhodium, iridium, nickel, or alloys thereof. In at least one embodiment, the top vias 130 are made from ruthenium for low electrical resistance and high resistance to electromigration. As such, the top vias 130 only form in the void created by removing the single individual mask 112 exposed at the bottom of the opening 128 (FIG. 7). As indicated in FIG. 8, the selective metal deposition technique used to form the top vias 130 may overfill the opening and result in a small portion of the conductive material extending above a top surface of the first dielectric layer 114. Doing so will prevent unwanted air gaps in the top vias 130.

Additionally, the same or different material combinations may be used to produce desired electrical resistance characteristics. For example, according to at least one embodiment, both the first metal lines 110 and the aligned top vias 130 are made from ruthenium. According to another embodiment, the first metal lines 110 are made from ruthenium and the top vias 130 are made from ruthenium, cobalt, or tungsten. According to yet another embodiment, the first metal lines 110 are made from tungsten, cobalt, or copper and the top vias 130 are made from ruthenium. Ruthenium is particularly advantageous for its superior electromigration properties thus eliminating the need for a barrier layer or liner layer. The resulting conductive structures, here the first metal lines 110 and the top vias 130, will have a larger volume as compared with similar structures made from copper.

Additionally, the top vias 130 are considered to be self-aligned with the single first metal line 110. This is made possible because the single first metal line 110 was patterned based on the single individual mask 112 which is then replaced in its entirety with the top vias 130. Additionally, a width of each of the top vias 130 is defined by the individual mask 112 in the y-direction, and a length of each of the top vias 130 is defined by the planarization player 124 in the x-direction.

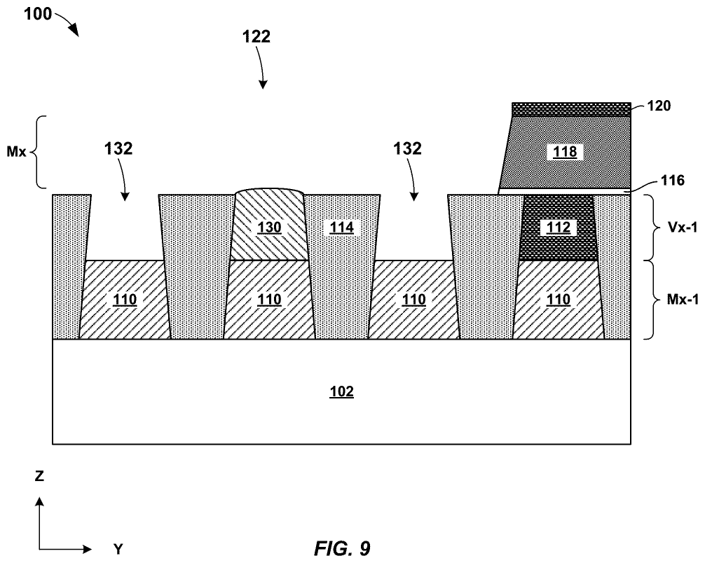

Referring now to FIG. 9, the structure 100 is shown after removing additional individual masks 112 exposed in the trenches 122 according to an embodiment of the invention.

The additional individual masks 112 exposed at the bottom of the trenches 122 are removed selective to the underlying structures as illustrated and according to known techniques. Doing so creates additional openings 132. For example, in at least one embodiment, additional individual masks 112 are removed selective to the first dielectric layer 114 and the first metal lines 110, as illustrated. One or more suitable etching techniques such as dry etch, wet etch, or combination of both may be used to remove the additional individual masks 112. For example, suitable dry etching techniques may include, but are not limited to: reactive ion etching (RIE), ion beam etching, plasma etching, or laser ablation. In doing so, the sacrificial mask 120 will be recessed. It is critical, that the sacrificial mask 120 should be sufficiently thick enough such that at least a portion remains after removing the additional individual mask 112, as illustrated in FIG. 9. Additionally, of note, only the additional individual masks 112 exposed within the trenches 122 will be removed. Said differently, one or more individual masks 112 and first metal lines 110 will remain protected beneath the remaining portions of the etch stop layer 116, second dielectric layer 118, and the sacrificial mask 120, as illustrated.

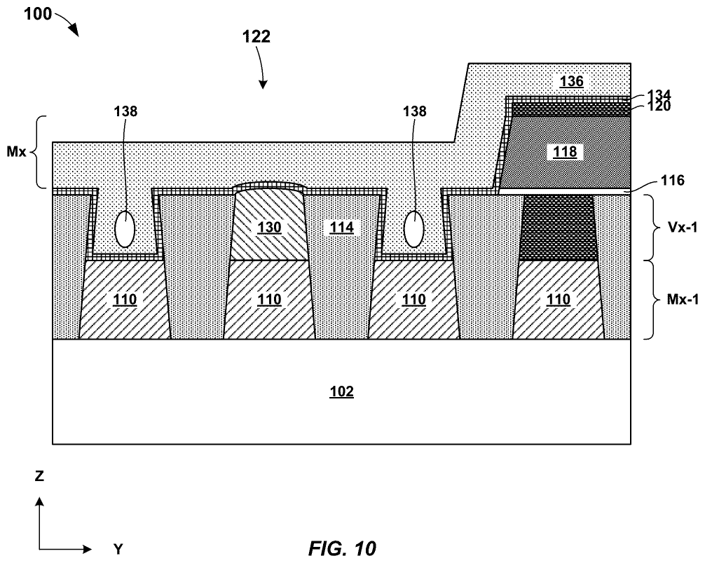

Referring now to FIG. 10, the structure 100 is shown after forming a liner 134 and a third dielectric layer 136 according to an embodiment of the invention. The liner 134 may alternatively be referred to as a dielectric liner 134.

First, the liner 134 of the present embodiment is conformally deposited directly on exposed surfaces of the structure 100 as illustrated and according to known techniques. As used herein, “conformal” it is meant that a material layer has a substantially continuous thickness. For example, a substantially continuous thickness generally means a first thickness as measured from a bottom surface to a topmost surface that is the same as a second thickness as measured from an inner sidewall surface to an outer sidewall surface. In another embodiment, the liner 134 may be a non-conformal layer.

The liner 134 is composed of a dielectric material suitable for providing suitable protection of underlying structures during subsequent processing. More specifically, the liner 134 can be any dielectric material that has some etch selectivity to the third dielectric layer 136 subsequently deposited, as is described in more detail immediately below. In at least one embodiment, the liner 134 is made from SiOC.

Next, the third dielectric layer 136 of the present embodiment is blanket deposited on top of the structure 100 and directly on top of the liner 134 as illustrated and according to known techniques. More specifically, the third dielectric layer 136 is deposited to fill the additional openings 132 (FIG. 9). The deposition thickness of the third dielectric layer 136 is immaterial so long as the additional openings 132 are completely filled with the third dielectric material.

The third dielectric layer 136 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-κ dielectrics, porous dielectrics, or some combination thereof. In an embodiment, the third dielectric layer 136 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

For example, in an embodiment, the third dielectric layer 136 is made from hydrogenated silicon carbon oxide (SiCOH). In another embodiment, the third dielectric layer 136 is made from carbon rich silicon carbon nitride (SiCN). In all cases, the third dielectric layer 136 should be formed of a dielectric material that has adequate etch selectivity with respect to the liner 134, as previously stated. According to at least one embodiment, both the third dielectric layer 136 and the first dielectric layer 114 are made from identical low-κ dielectrics. In at least another embodiment, both the third dielectric layer 136 and the first dielectric layer 114 are made from different low-κ dielectrics.

During deposition of the third dielectric layer 136, air gaps 138 form within the additional openings 132, as illustrated. More specifically, pinch-off occurs at the relatively narrow “mouth” of the additional openings 132 thus creating the air gaps 138. Although, formation of the air gaps 138 is very likely, it is possible, and thus explicitly contemplated that the air gaps 138 may not form at all or only form in some of the openings 132.

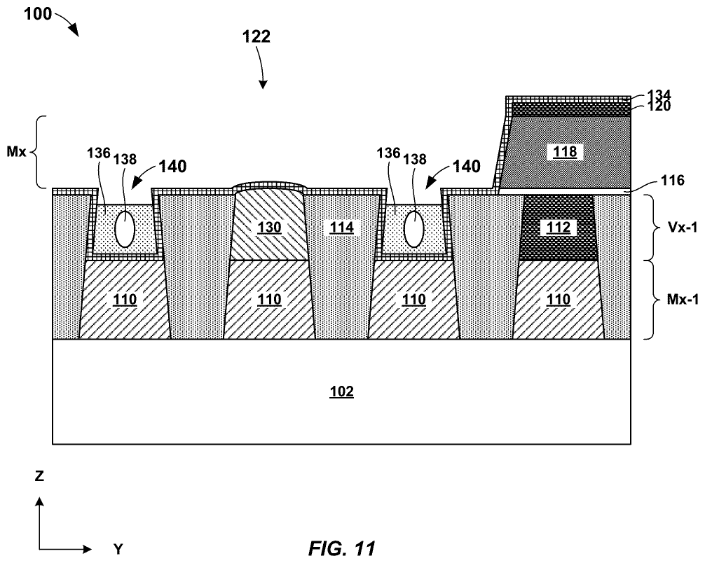

Referring now to FIG. 11, the structure 100 is shown after recessing the third dielectric layer 136 according to an embodiment of the invention.

The third dielectric layer 136 of the present embodiment is recessed as illustrated and according to known techniques. Specifically, for example, one or more suitable etching techniques such as dry etch, wet etch, or combination of both may be used to recess the third dielectric layer 136. After etching, portions of the third dielectric layer 136 remain within the additional openings 132 (FIG. 9), as illustrated.

In all cases, the chosen etching technique shall be selective to the liner 134.

Meanwhile, the liner 134 protects underlying structures from etching. Specifically, the selectivity of the liner 134 protects the sacrificial mask 120, the second dielectric layer 118, the etch stop layer 116, and the first dielectric layer 114, as illustrated. Etching continues until the bulk of the liner 134 at the bottom of the trenches 122 is exposed. In doing so, etching will more than likely continue until a small recess 140 forms in or at the additional openings 132, as illustrated. Although the small recess 140 is neither significant nor necessary, it is merely an outcome of exposing the liner 134 at the bottom of the trenches 122.

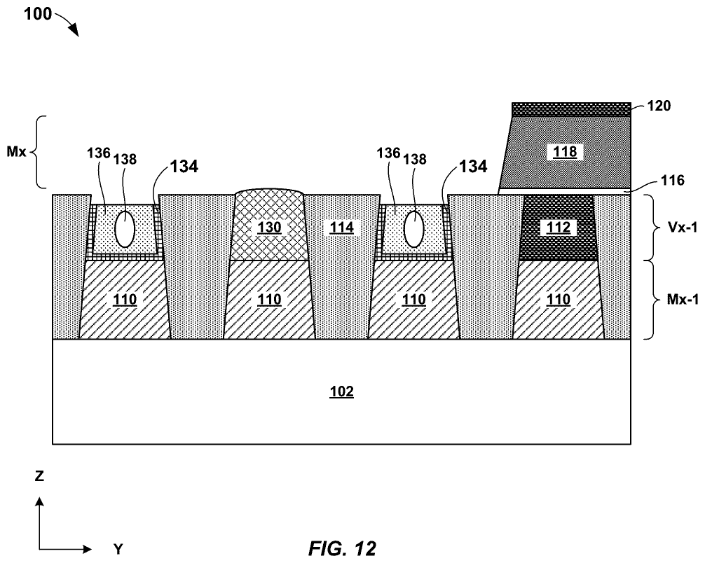

Referring now to FIG. 12, the structure 100 is shown after recessing the liner 134 according to an embodiment of the invention.

The liner 134 of the present embodiment is recessed as illustrated and according to known techniques. Specifically, for example, one or more suitable etching techniques such as dry etch, wet etch, or combination of both may be used to recess exposed portions of the liner 134. In all cases, the chosen etching technique shall be selective to underlying structures, such as for example, the sacrificial mask 120, the second dielectric layer 118, the etch stop layer 116, the aligned top vias 130, and the first dielectric layer 114, as illustrated.

Etching continues until the bulk of the liner 134 is removed leaving only portions within the additional openings 132. Specifically, after etching, portions of the liner 134 remain covered by remaining portions of the third dielectric layer 136. In all cases, etching of the liner 134 must expose a top surface of the top vias 130. In doing so, etching will more than likely continue until a small recess 140 forms in or at the additional openings 132, as illustrated. Although the small recess 140 is neither significant nor necessary, it is merely an outcome of exposing the liner 134 at the bottom of the trenches 122.

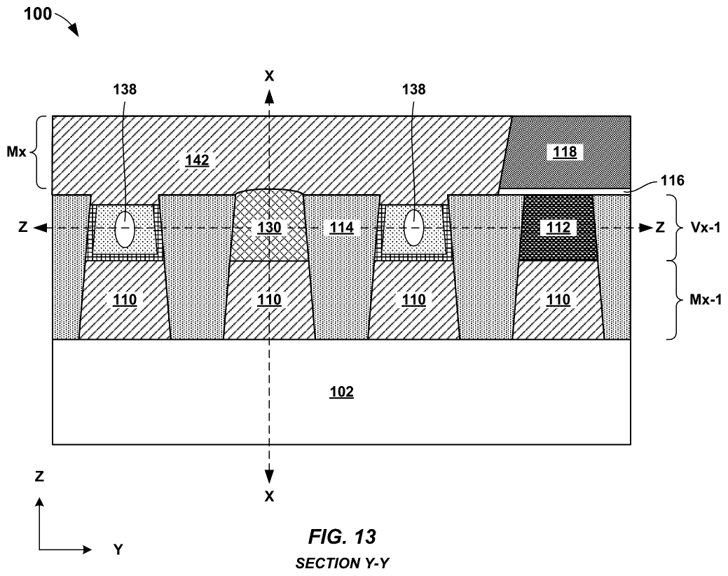

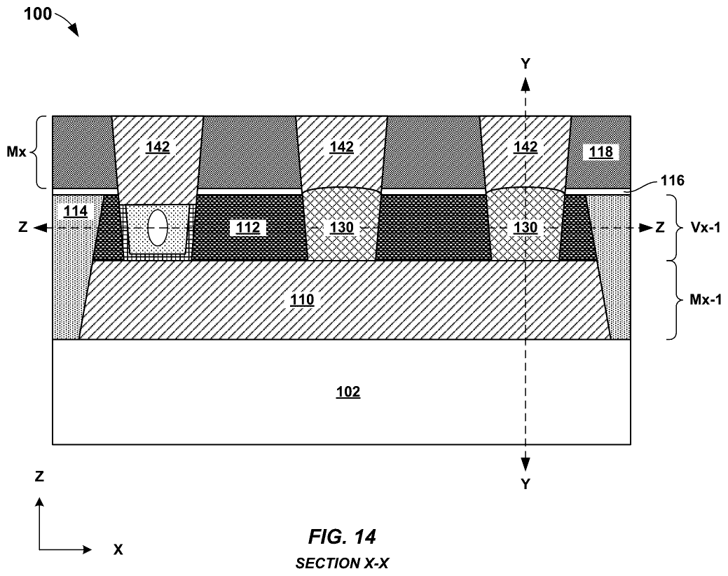

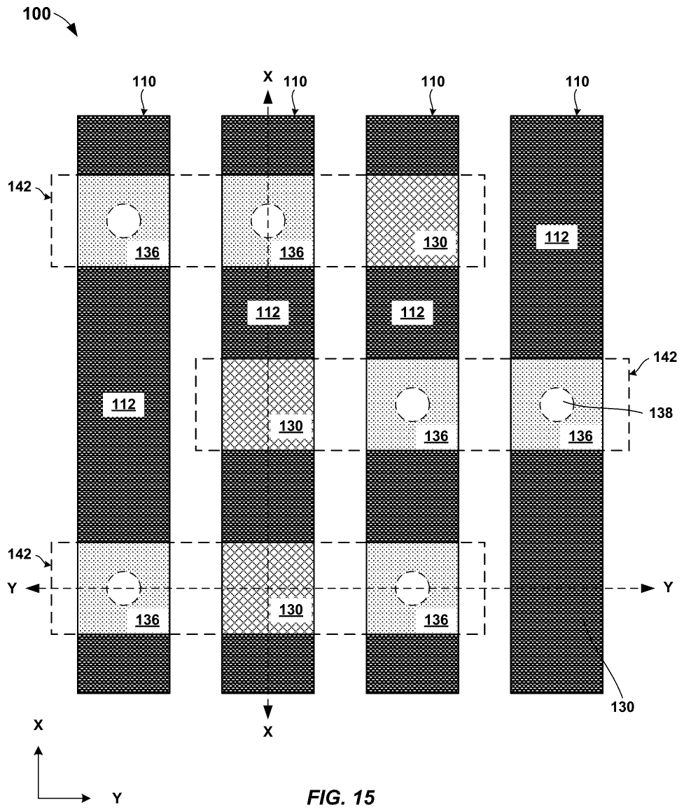

Referring now to FIGS. 13, 14, and 15, the structure 100 is shown after forming second metal lines 142 according to an embodiment of the invention. FIG. 13 depicts a cross-sectional view of the structure 100 shown in FIG. 15 taken along line X-X. FIG. 14 depicts a cross-sectional view of the structure 100 shown in FIG. 15 taken along line Y-Y. FIG. 15 depicts a cross-sectional view of the structure 100 shown in FIGS. 13 and 14 taken along line Z-Z. For purposes of clarity and understanding, some elements are omitted from FIG. 15, for example, surrounding dielectric layers.

The second metal lines 142 of the present embodiment are formed within the trenches 122 as illustrated and according to known techniques. As such, the second metal lines 110 are embedded in the second dielectric layer 118. Despite only a single second metal line being depicted in FIG. 13, embodiments of the present invention explicitly contemplate forming multiple second metal lines, as shown in FIG. 14.

The second metal lines 142 can include any suitable interconnect metal which may be easily deposited within a single damascene trench. For example, the second metal lines 142 can include aluminum, copper, ruthenium, cobalt, rhodium, iridium, nickel, or alloys thereof or the like as desired for the application. In at least one embodiment, the second metal lines 142 are made from copper in a damascene fashion. The second metal lines 142 can be deposited using known techniques, such as, for example, CVD, sputtering, electrochemical deposition or like processes. The thickness of the second metal lines 142 will correspond with the relative thickness of the second dielectric layer 118, which as previously described, is approximately equal to a desired thickness of a typical metallization level. In some embodiments, an adhesion layer (not shown) is first deposited within the trenches 122 prior to depositing the second metal line 142. In such cases, the adhesion layer may be a relatively thin layer of titanium nitride.

In general, the second metal lines 142 are fabricated using known damascene techniques. As such, the top vias 130 will also be self-aligned to a single second metal line 142. Stated differently, the top vias 130 are self-aligned to the single first metal line 110 in the y-direction and self-aligned to the single second metal line 142 in the x-direction.

In sum, for purposes of this description the structure 100 illustrated in the figures and described herein includes multiple interconnect levels positioned one on top of another, and manufactured in a process flow. Embodiments of the present invention, and the detailed description provide above, are directed primarily at the formation of the top vias 130 with improved performance characteristics (ie lower capacitance between metal levels).

As illustrated in FIGS. 13-15, the interconnect structures represented by the structure 100 has some distinctive notable features. Unlike conventional structures, no masking material (e.g. masks 112) remain directly beneath the second metal lines 142, and between the first metal lines 110 and the second metal lines 142. After forming the top vias 130, those masks 112 in positions not otherwise occupied by the top vias 130 typically remain in conventional structures. The existence of the “left-over” masks 112 directly between the first metal lines 110 and the second metal lines 142 causes unwanted increase in capacitance between the metal levels. The unwanted capacitance between metal levels is caused by the relatively higher κ value of the “left-over” masks 112. It is noted, embodiments of the present invention specifically contemplate removing any “left-over” masks 112, as illustrated in the figures. Therefore, removing “left-over masks 112, as described with reference to FIG. 9, effectively reduces the unwanted capacitance between metal levels.

Additionally, removed portions of the masks 112 are replaced with a dielectric material, which in some cases will result in the air gaps 138. Such air gaps 138 will be present at those locations which the “left-over” masks 112 were removed. Formation of the air gaps 138 is extremely process dependent and thus it is further explicitly contemplated that the air gaps 138 may not be present at all in some embodiments. It is further explicitly contemplated that the air gaps 138 may be present in only some regions and not others in some embodiments.

With continued reference to FIGS. 13-15, and according to an embodiment, the structure 100 includes first metal lines 110 embedded in a first dielectric layer 114, second metal lines 142 embedded in a second dielectric layer 118, where the second metal lines 142 arranged above the first metal lines 110, a top via 130 extending between one of the first metal lines (110) and one of the second metal lines (142), where the top via 130 is self-aligned to the one of the first metal lines (110), and at least one air gap 138 located adjacent to the top via 130 between the first metal lines 110 and the second metal lines 242.

With continued reference to FIGS. 13-15, and according to an embodiment, the structure 100 further includes a dielectric liner 134 surrounding sides and a bottom of the at least one air gap 138.

With continued reference to FIGS. 13-15, and according to an embodiment, the dielectric liner 134 directly contacts all topmost surfaces of the first metal lines directly beneath the second metal lines 142 except where the top via 130 is positioned.

With continued reference to FIGS. 13-15, and according to an embodiment, the structure 100 further includes masks 112 above and directly contacting topmost surfaces of the first metal lines 110 except where the first metal lines 110 are directly beneath the second metal lines 142, wherein bottom most surfaces of the masks 112 are substantially flush with a bottom most surface of the top via 130.

With continued reference to FIGS. 13-15, and according to an embodiment, bottom most surfaces of the second metal lines 142 are below a topmost surface of the first dielectric layer 114.

With continued reference to FIGS. 13-15, and according to an embodiment, the first metal lines 110 directly contact the first dielectric layer 114 without a barrier liner, the top via 130 directly contacts the first dielectric layer 114 without a barrier liner, and the second metal lines 142 directly contact both the first dielectric layer 114 and the second dielectric layer 118 without a barrier liner.

With continued reference to FIGS. 13-15, and according to an embodiment, the first metal lines 110 and the second metal lines 142 comprise ruthenium.

With continued reference to FIGS. 13-15, and according to an embodiment, the structure 100 includes first metal lines 110 embedded in a first dielectric layer 114, second metal lines 142 embedded in a second dielectric layer 118, where the second metal lines 142 are arranged above the first metal lines 110, a top via 130 extending between one of the first metal lines (110) and one of the second metal lines (142), where the top via 130 is self-aligned to the one of the first metal lines (110), and at least one air gap 138 located adjacent to the top via 130 between the first metal lines 110 and the second metal lines 142, where the at least one air gap 138 is in the same level as the top via 130.

With continued reference to FIGS. 13-15, and according to an embodiment, the structure 100 includes first metal lines 110 embedded in a first dielectric layer 114, second metal lines 142 embedded in a second dielectric layer 118, where the second metal lines 142 are arranged above the first metal lines 110, a top via 130 extending between one of the first metal lines (110) and one of the second metal lines (142), where the top via 130 is self-aligned to the one of the first metal lines (110), and at least one air gap 138 located in the same level as the top via 130, where the at least one air gap 138 is arranged at intersections (see FIG. 15) between the first metal lines 110 and the second metal lines 142.

With continued reference to FIGS. 13-15, and according to an embodiment, the structure 100 includes first metal lines 110 embedded in a first dielectric layer 114, second metal lines 142 embedded in a second dielectric layer 118, where the second metal lines 142 are arranged above the first metal lines 110, a top via 130 extending between one of the first metal lines (110) and one of the second metal lines (142), where the top via 130 is self-aligned to the one of the first metal lines (110), and at least one air gap 138 located in the same level as the top via 130, where the at least one air gap 138 is arranged at intersections (see FIG. 15) between the first metal lines and the second metal lines, a dielectric liner 134 surrounding sides and a bottom of the at least one air gap 138, masks 112 above and directly contacting topmost surfaces of the first metal lines 110 except where the first metal lines 110 are directly beneath the second metal lines 142, wherein bottom most surfaces of the masks 112 are substantially flush with a bottom most surface of the top via 130.

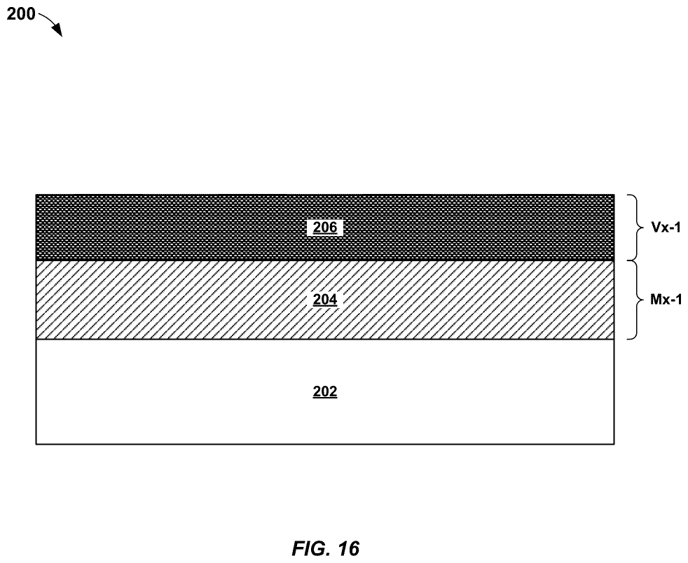

Referring now to FIG. 16, a demonstrative illustration of a second structure 200 (hereinafter structure 200) is shown during an intermediate step of a method of fabricating an interconnect structure according to an embodiment of the invention. More specifically, as disclosed herein, the method may begin with an underlying level 202 having a first metal layer 204 and a first hard mask layer 206 formed thereon.

For purposes of the present description, the underlying level 202 represents any one of a front-end-of-line device layer, a middle-of-line metal layer, or a back-end-of-line metal layer. In at least one example, the underlying level 202 may include one or more contacts or contact vias present in a front-end-of-line device layer or a back-end-of-line metal layer. In yet another example, the underlying level 202 may include one or more metal lines, via or other conductors present in a middle-of-line metal layer or a back-end-of-line metal layer.

The first metal layer 204 of the present embodiment is formed directly on top of the underlying level 202 according to known techniques. The first metal layer 204 can include any suitable interconnect metal which may be easily removed by a subtractive etch. For example, the first metal layer 204 can include aluminum, copper, ruthenium, cobalt, rhodium, iridium, nickel, or alloys thereof or the like as desired for the application. In at least one embodiment, the first metal layer 204 is made from ruthenium for low electrical resistance and high resistance to electromigration. The first metal layer 204 can be deposited using known techniques, such as, for example, CVD, sputtering, electrochemical deposition or like processes. In an embodiment, the thickness of the first metal layer 204 can range from approximately 20 nm to approximately 100 nm; however, other thicknesses lesser than 20 nm and greater than 100 nm are explicitly contemplated. In some embodiments, an adhesion layer (not shown) is provided between the underlying level 202 and the first metal layer 204. In such cases, the adhesion layer may be a relatively thin layer of titanium nitride.

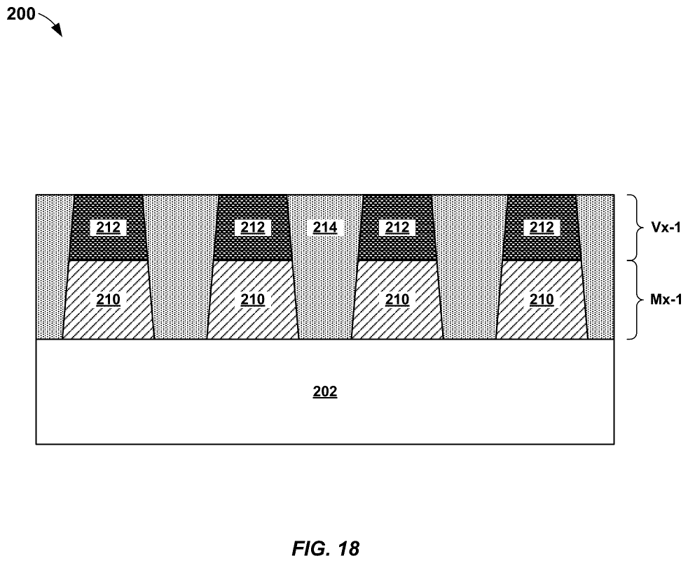

Finally, the first hard mask layer 206 of the present embodiment is formed directly on top of the first conductive layer 204 as illustrated and according to known techniques. The first hard mask layer 206 can include any known dielectric hard mask materials suitable for facilitating subsequent patterning and etching techniques. In all cases, the first hard mask layer 206 is preferably made from a dielectric material which is capable of being etched or patterned selective to a first dielectric layer (FIG. 18) and the metal lines 210. For example, the first hard mask layer 206 can include nitrides, such as, silicon nitride, titanium nitride, tantalum nitride, aluminum nitride, or silicon carbon nitride. In at least one embodiment, for example, the first hard mask layer 206 is a layer of silicon nitride. In another embodiment, the first hard mask layer 206 is a layer of silicon carbon nitride. Finally, the first hard mask layer 206 is sacrificial in nature because some or all of it will be removed during subsequent processes and will no longer be present in the final structure. The first hard mask layer 206 can be formed by any deposition technique including, for example, chemical vapor deposition (CVD), plasma enhanced chemical vapor deposition (PECVD), physical vapor deposition (PVD), sputtering, or atomic layer deposition.

The cumulative thickness of the first metal layer 204 and the first hard mask layer 206 is approximately equal to a desired thickness of a typical metallization level formed on, and subsequent to, the underlying level 202. Specifically, the relative thickness of the first metal layer 204 corresponds to a desired height or thickness of a typical metal level (eg Mx−1) and the relative thickness of the first hard mask layer 206 corresponds to a desired height or thickness of a typical via level (eg Vx−1). In some embodiments, the thickness of the first hard mask layer 206 is substantially equal to the thickness of the first metal layer 204. In other embodiments, the first hard mask layer 206 can be thicker than the first metal layer 204. In yet other embodiments, the first hard mask layer 206 can be thinner than the first metal layer 204. It is noted, a final height of subsequently formed metal lines and top vias are not solely dependent on the relative height or thickness of either the first metal layer 204 or the first hard mask layer 206 respectively.

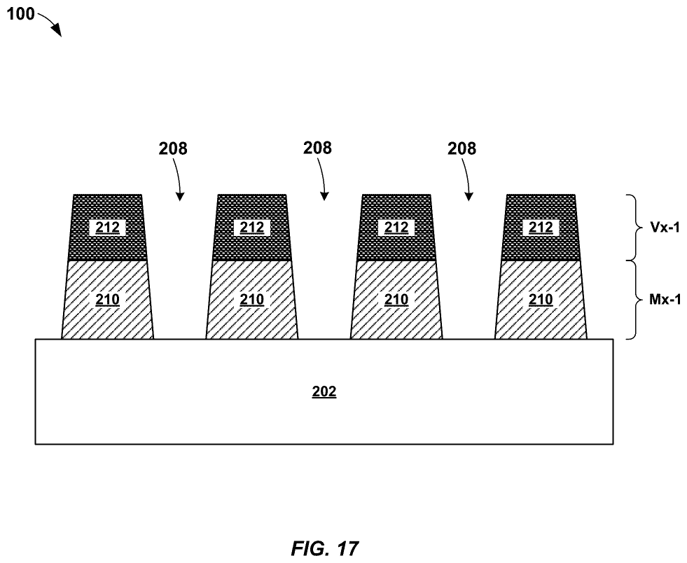

Referring now to FIG. 17, the structure 200 is shown after patterning openings 208 in the first metal layer 204 and exposing the underlying level 202 according to an embodiment of the invention.

The openings 208 of the present embodiment are patterned in the structure 200 according to known techniques. The openings 208 may be patterned by applying a photoresist (not shown), and exposing the photoresist to a desired pattern of radiation and developing the exposed photoresist utilizing a conventional resist developer. The pattern in the photoresist may then be transferred to the first hard mask layer 206 and the first metal layer 204 according to known techniques. For example, one or more suitable etching techniques such as dry etch, wet etch, or combination of both may be used to pattern the openings 208.

After patterning, remaining portions of the first hard mask layer 206 become a plurality of individual masks 212, and remaining portions of the first metal layer 204 become first metal lines 210, as illustrated. The first metal lines 210 formed according to the processes described herein are formed according to convention subtractive techniques.

In general, the openings 208, and similarly the first metal lines 210, may be spaced apart according to lithography limitations, ground rules, or both. In some embodiments, the openings 208 are spaced equal distances apart; however, doing so is not required. Finally, only three openings 208 are shown in FIG. 17 for illustrative purposes only. As is well known by persons having ordinary skill in the art, any typical semiconductor structure will have multiple back-end-of-line interconnect structures, the structure 200 of the present invention also explicitly includes multiple openings 208 despite not being shown in the figures.

Referring now to FIG. 18, the structure 200 is shown after forming a first dielectric layer 214 according to an embodiment of the invention.

The first dielectric layer 214 of the present embodiment is blanket deposited on top of the structure 200, and more specifically filling the openings 208 as illustrated and according to known techniques.

The first dielectric layer 214 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-κ dielectrics, porous dielectrics, or some combination thereof. The term “low-κ” as used herein refers to a material having a relative dielectric constant k which is lower than that of silicon dioxide. In an embodiment, the first dielectric layer 214 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

For example, in an embodiment, the first dielectric layer 214 is made from hydrogenated silicon carbon oxide (SiCOH). In another embodiment, the first dielectric layer 214 is made from carbon rich silicon carbon nitride (SiCN). In all cases, the first dielectric layer 214 should be formed of a dielectric material that has adequate etch selectivity with respect to surrounding dielectric, for example the individual masks 212, as well as other subsequently formed materials as discussed below.

Finally, a chemical mechanical polishing technique is used to remove excess unwanted dielectric material from upper surfaces of the structure 200. As a result, topmost surfaces of the first dielectric layer 214 will be flush, or substantially flush with topmost surfaces of the individual masks 212.

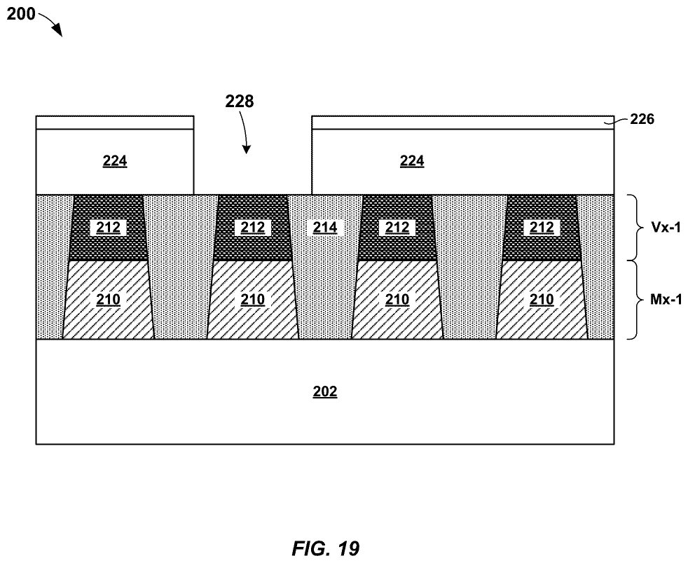

Referring now to FIG. 19, the structure 200 is shown after forming a planarization layer 224 and a second hard mask layer 226 in accordance with an embodiment of the present invention.

The planarization layer 224 of the present embodiment is blanket deposited directly on exposed surfaces of the structure 200 as illustrated and according to known techniques. The planarization layer 224 can be an organic planarization layer or a layer of material that is capable of being planarized or etched by known techniques. In an embodiment, for example, the planarization layer 224 can be an amorphous carbon layer able to withstand the high temperatures of subsequent processing steps. The planarization layer 224 can preferably have a thickness sufficient to cover existing structures.

Next, the second hard mask layer 226 of the present embodiment is deposited directly on the planarization layer 224 as illustrated and according to known techniques. The second hard mask layer 226 can include any known hard mask materials suitable for facilitating subsequent patterning and etching techniques. In all cases, the second hard mask layer 226 is preferably made from a material which is capable of being etched or patterned selective to the planarization layer 224 and other surrounding metal features. Like the first hard mask layer 206, for example, the second hard mask layer 126 can include known antireflective coatings, such as, SiARC, TiARC, TiOx, LTO, SiON, etc. Finally, the second hard mask layer 226 is sacrificial in nature because it will be removed during subsequent processes and will no longer be present in the final structure. The second hard mask layer 226 can be formed by any deposition technique including, for example, chemical vapor deposition (CVD), plasma enhanced chemical vapor deposition (PECVD), physical vapor deposition (PVD), sputtering, or atomic layer deposition. Finally, the second hard mask layer 226 and the planarization layer 224, both of the present embodiment, are patterned to create an opening 228 as illustrated and according to known techniques. The opening 228 is arranged to expose a single individual mask 212, as illustrated. Similarly, the opening 228 is arrange directly above a single first metal line 210, also as illustrated.

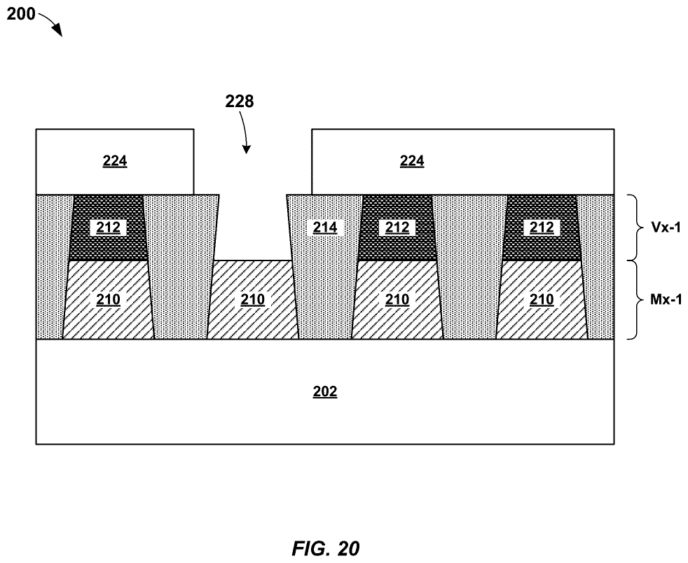

Referring now to FIG. 20, the structure 200 is shown after removing the single individual mask 212 exposed at the bottom of the opening 228 and removing the second hard mask layer 226 according to an embodiment of the invention.

The single individual mask 212 exposed at the bottom of the opening 228 and the second hard mask layer 226 are removed selective to the underlying structures as illustrated and according to known techniques. For example, in at least one embodiment, the single individual mask 212 is removed selective to the first dielectric layer 214 and the first metal lines 210, and the second hard mask layer 226 is removed selective to the planarization layer 224. One or more suitable etching techniques such as dry etch, wet etch, or combination of both may be used to remove the single individual mask 212 and the second hard mask layer 226. For example, suitable dry etching techniques may include, but are not limited to: reactive ion etching (RIE), ion beam etching, plasma etching, or laser ablation. The primary purpose of this etch is to remove the single individual mask 212, and removal of the second hard mask layer 226 is a consequence when similar hard mask materials are used. Embodiments of the present invention explicitly contemplate the single individual mask 212 and the second hard mask layer 226 being different hard mask materials thus requiring an additional etching step to remove the second hard mask layer 226, despite doing so being less efficient.

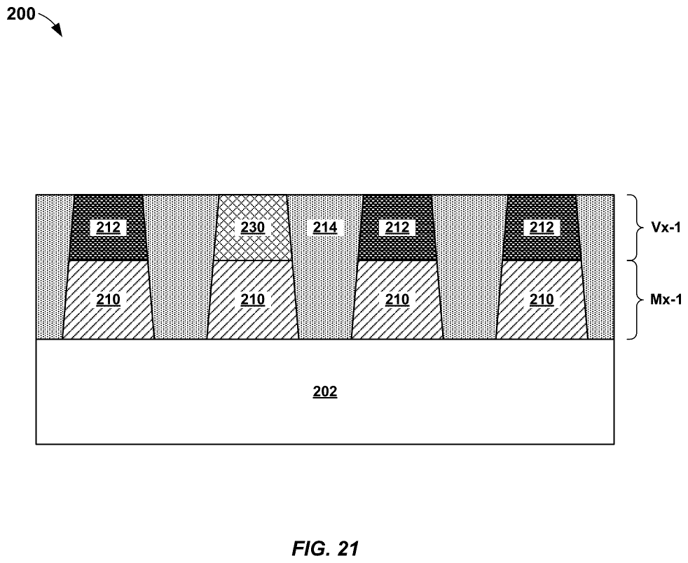

Referring now to FIG. 21, the structure 200 is shown after forming self-aligned top vias 230, and removing the planarization layer 224 according to an embodiment of the invention.

First, the self-aligned top vias 230 (hereinafter top vias 230) of the present embodiment is formed directly on top of the single first metal line 210 as illustrated and according to known techniques. Specifically, the void created by removing the single individual mask 212 exposed at the bottom of the opening 228 (FIG. 20) is filled with a conductive material to form the top vias 230. For example, known CVD or ALD techniques may be used to selectively deposit the metals, such as, for example, tungsten, ruthenium, aluminum, copper, ruthenium, cobalt, rhodium, iridium, nickel, or alloys thereof. In at least one embodiment, the top vias 230 are made from ruthenium for low electrical resistance and high resistance to electromigration. As such, the top vias 230 only form in the void created by removing the single individual mask 212 exposed at the bottom of the opening 228 (FIG. 20). A chemical mechanical polishing technique is used to remove excess unwanted conductive material from upper surfaces of the structure 200. As a result, topmost surfaces of the first dielectric layer 114 will be flush, or substantially flush with topmost surfaces of the individual masks 212 as well as topmost surfaces of the first dielectric layer 214.

Additionally, the same or different material combinations may be used to produce desired electrical resistance characteristics. For example, according to at least one embodiment, both the first metal lines 210 and the top vias 230 are made from ruthenium. According to another embodiment, the first metal lines 210 is made from ruthenium and the top vias 230 is made from ruthenium, cobalt, or tungsten. According to yet another embodiment, the first metal lines 210 is made from tungsten, cobalt, or copper and the top vias 230 is made from ruthenium. Ruthenium is particularly advantageous for its superior electromigration properties thus eliminating the need for a barrier layer or liner layer. The resulting conductive structures, here the first metal lines 210 and the top vias 230, will have a larger volume as compared with similar structures made from copper.

Additionally, the top vias 230 are considered to be self-aligned with the single first metal line 210. This is made possible because the single first metal line 210 was patterned based on the single individual mask 212 which is then replaced in its entirety with the top vias 230. Additionally, a width of each of the top vias 230 is defined by the individual mask 212 in the y-direction, and a length of each of the top vias 230 is defined by the planarization player 224 in the x-direction.

Next, the planarization layer 224 is removed selective to all underlying structures as illustrated and according to known techniques. For example, in at least one embodiment, the planarization layer 224 is removed by ashing.

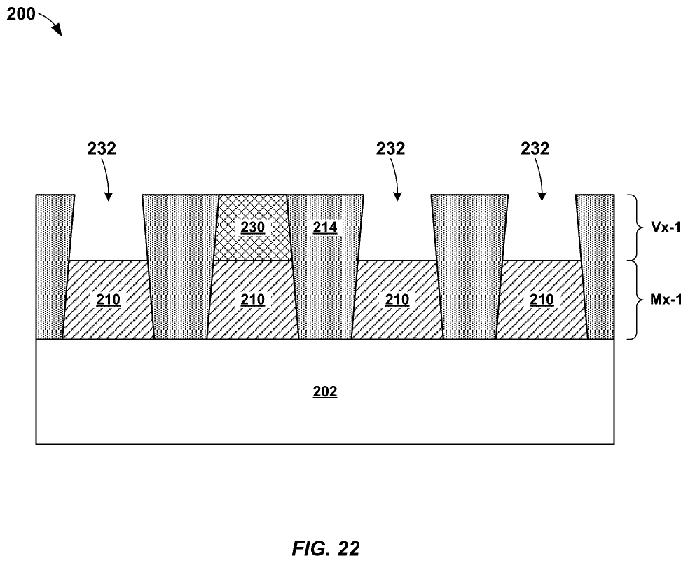

Referring now to FIG. 22, the structure 200 is shown after removing remaining individual masks 212 according to an embodiment of the invention.

The remaining individual masks 212 are removed selective to the underlying structures as illustrated and according to known techniques. Doing so creates additional openings 232. For example, in at least one embodiment, remaining individual masks 212 are removed selective to the first dielectric layer 214 and the first metal lines 210, as illustrated. One or more suitable etching techniques such as dry etch, wet etch, or combination of both may be used to remove the remaining individual masks 212. For example, suitable dry etching techniques may include, but are not limited to: reactive ion etching (RIE), ion beam etching, plasma etching, or laser ablation.

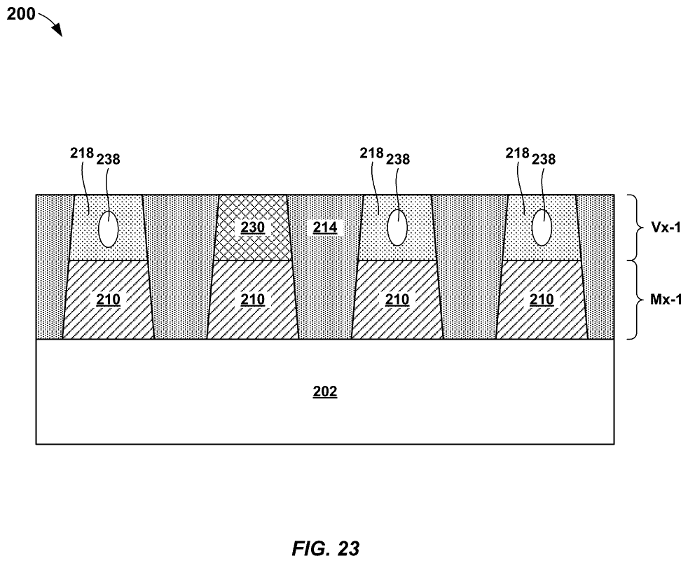

Referring now to FIG. 23, the structure 200 is shown after forming a second dielectric layer 218 according to an embodiment of the invention.

First, the second dielectric layer 218 of the present embodiment is blanket deposited on top of the structure 200 as illustrated and according to known techniques. More specifically, the second dielectric layer 218 is deposited to fill the additional openings 232 (FIG. 22). The deposition thickness of the second dielectric layer 218 is immaterial so long as the additional openings 232 are completely filled with the third dielectric material.

The second dielectric layer 218 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-κ dielectrics, porous dielectrics, or some combination thereof. In an embodiment, the second dielectric layer 218 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

For example, in an embodiment, the second dielectric layer 218 is made from hydrogenated silicon carbon oxide (SiCOH). In another embodiment, the second dielectric layer 218 is made from carbon rich silicon carbon nitride (SiCN). According to at least one embodiment, both the second dielectric layer 218 and the first dielectric layer 214 are made from identical low-κ dielectrics. In at least another embodiment, both the second dielectric layer 218 and the first dielectric layer 214 are made from different low-κ dielectrics.

During deposition of the second dielectric layer 218, air gaps 238 form within the additional openings 232, as illustrated. More specifically, pinch-off occurs at the relatively narrow “mouth” of the additional openings 232 thus creating the air gaps 238. Although, formation of the air gaps 238 is very likely, it is possible, and thus explicitly contemplated that the air gaps 238 may not form at all or only form in some of the openings 232.

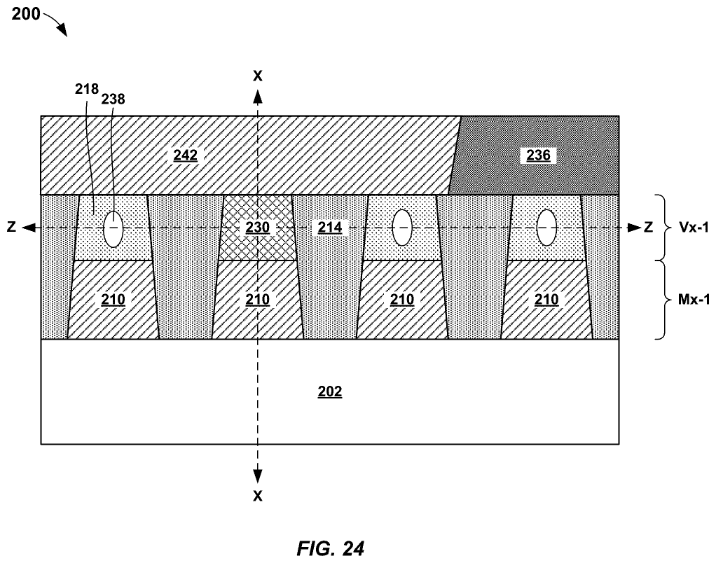

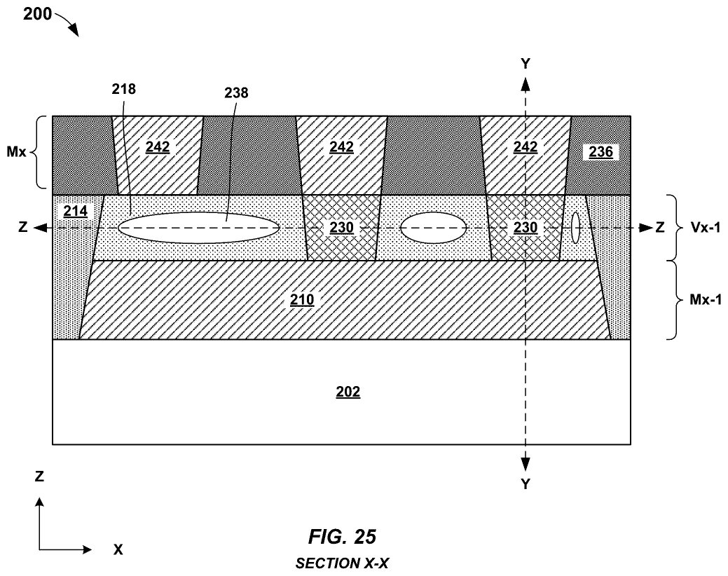

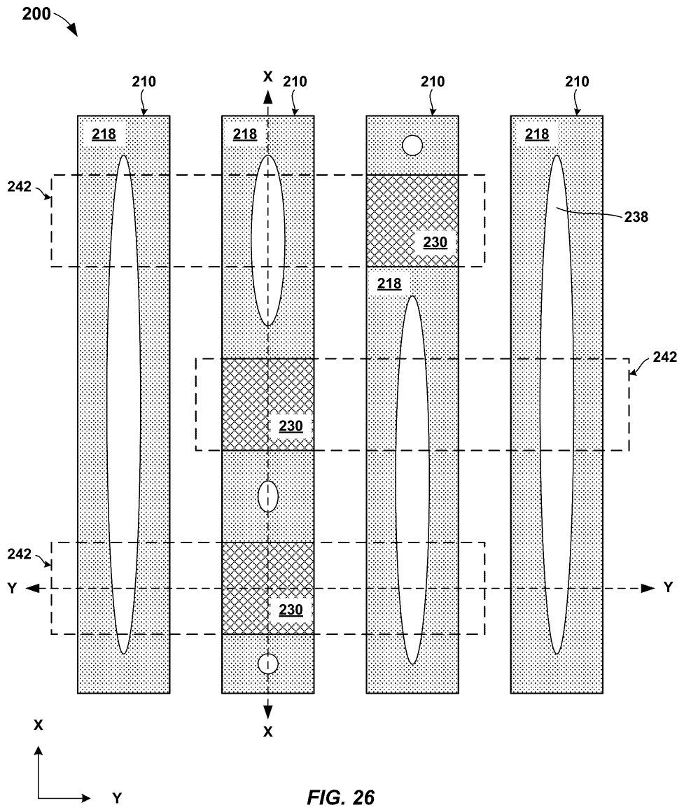

Referring now to FIGS. 24, 25, and 26, the structure 200 is shown after forming second metal lines 242 and a third dielectric layer 236 according to an embodiment of the invention. FIG. 24 depicts a cross-sectional view of the structure 100 shown in FIG. 26 taken along line X-X. FIG. 25 depicts a cross-sectional view of the structure 100 shown in FIG. 26 taken along line Y-Y. FIG. 26 depicts a cross-sectional view of the structure 100 shown in FIGS. 24 and 25 taken along line Z-Z. For purposes of clarity and understanding, some elements are omitted from FIG. 26, for example, surrounding dielectric layers.

The second metal lines 242 of the present embodiment are formed as illustrated and according to known techniques. Despite only a single second metal line being depicted in FIG. 24, embodiments of the present invention explicitly contemplate forming multiple second metal lines, as shown in FIGS. 25 and 26.

The second metal lines 242 can include any suitable interconnect metal which may be easily formed by way of conventional damascene or subtractive techniques. For example, the second metal lines 242 can include aluminum, copper, ruthenium, cobalt, rhodium, iridium, nickel, or alloys thereof or the like as desired for the application. In at least one embodiment, the second metal lines 242 are formed according to known damascene techniques. In at least another embodiment (not shown), the second metal lines 242 are subtractivly formed from ruthenium for low electrical resistance and high resistance to electromigration. Initially in a subtractive scheme, the conductive material chosen for the second metal lines 242 is blanket deposited using known techniques, such as, for example, CVD, sputtering, electrochemical deposition or like processes. The thickness of the chosen conductive material is approximately equal to a desired thickness of a typical metallization level, as previously described. In an embodiment, the thickness of the blanket layer can range from approximately 20 nm to approximately 100 nm; however, other thicknesses lesser than 20 nm and greater than 100 nm are explicitly contemplated. In some embodiments, an adhesion layer (not shown) is first deposited prior to depositing the second metal line 242; however, such is not necessary. In such cases, the adhesion layer may be a relatively thin layer of titanium nitride.

In general, and according to the illustrated embodiment, the second metal lines 242 are fabricated using known subtractive techniques. As such, the top vias 230 will not be self-aligned to a single second metal line 242. Stated differently, the top vias 230 are self-aligned to the single first metal line 110 in the y-direction, but not self-aligned to the single second metal line 142 in any direction. If in an alternative embodiment, the second metal lines 242 were formed using known damascene techniques.

Finally, the second dielectric layer 236 of the present embodiment is blanket deposited on top of the structure 100 as illustrated and according to known techniques. Like the first dielectric layer 214, the second dielectric layer 236 may include any suitable dielectric material, for example, oxide, nitride, silicon oxide (SiO₂), silicon nitride (Si₃N₄), hydrogenated silicon carbon oxide (SiCOH), carbon rich silicon carbon nitride (SiCN), silicon based low-κ dielectrics, porous dielectrics, or some combination thereof. In an embodiment, the second dielectric layer 236 can be formed using a deposition technique including, for example, chemical vapor deposition (CVD), plasma enhanced chemical vapor deposition (PECVD), physical vapor deposition (PVD), atomic layer deposition (ALD), evaporation, spin-on coating, or sputtering.

For example, in an embodiment, the second dielectric layer 236 is made from hydrogenated silicon carbon oxide (SiCOH). In another embodiment, the second dielectric layer 236 is made from carbon rich silicon carbon nitride (SiCN). According to at least one embodiment, the second dielectric layer 236 is made from an identical dielectric material as the first dielectric layer 214. In at least another embodiment, the second dielectric layer 236 is made from a different material than the first dielectric layer 214.

The relative thickness of the second dielectric layer 236 is approximately equal to a desired thickness of a typical metallization level formed on, and subsequent to, the underlying Mx−1 and Vx−1 levels. Specifically, the relative thickness of the second dielectric layer 236 corresponds to a desired height or thickness of a typical metal level (eg Mx).

In sum, for purposes of this description the structure 200 illustrated in the figures and described herein includes multiple interconnect levels positioned one on top of another, and manufactured in a process flow. Embodiments of the present invention, and the detailed description provide above, are directed primarily at the formation after a self-aligned top via 230 with improved performance characteristics (ie lower capacitance between metal levels).

As illustrated in FIGS. 24-26, the interconnect structures represented by the structure 200 has some distinctive notable features. Unlike conventional structures, no masking material (e.g. masks 212) remain directly beneath the second metal lines 242, and between the first metal lines 210 and the second metal lines 242. After forming the top vias 230, those masks 212 in positions not otherwise occupied by the top vias 230 typically remain in conventional structures. The existence of the “left-over” masks 112 directly between the first metal lines 210 and the second metal lines 242 causes unwanted increase in capacitance between the metal levels. The unwanted capacitance between metal levels is caused by the relatively higher κ value of the “left-over” masks 212. It is noted, embodiments of the present invention specifically contemplate removing any “left-over” masks 212, as illustrated in the figures. Therefore, removing “left-over” masks 212, as described with reference to FIG. 22, effectively reduces the unwanted capacitance between metal levels. As further illustrated in FIG. 26 all remaining portions of the masks 212 except where the top vias 230 are present are removed. Additionally, removed portions of the masks 212 are replaced with a dielectric material, which in some cases will result in the air gaps 238. Such air gaps 238 will be present at those locations which the “left-over” masks 212 were removed. Formation of the air gaps 238 is extremely process dependent and thus it is further explicitly contemplated that the air gaps 238 may not be present at all in some embodiments. It is further explicitly contemplated that the air gaps 238 may be present in only some regions and not others in some embodiments.

With continued reference to FIGS. 24-26, and according to an embodiment, the structure 200 includes first metal lines 210 embedded in a first dielectric layer 214, second metal lines 242 embedded in a second dielectric layer 236, where the second metal lines 242 arranged above the first metal lines 210, a top via 230 extending between one of the first metal lines (210) and one of the second metal lines (242), where the top via 130 is self-aligned to the one of the first metal lines (210), and at least one air gap 238 located adjacent to the top via 230 between the first metal lines 210 and the second metal lines 242.

With continued reference to FIGS. 24-26, and according to an embodiment, wherein the first metal lines 210 directly contact the first dielectric layer 214 without a barrier liner, where the top via 230 directly contacts the first dielectric layer 214 without a barrier liner, and where the second metal lines 242 directly contact both the first dielectric layer 214 and the second dielectric layer 236 without a barrier liner.

With continued reference to FIGS. 24-26, and according to an embodiment, the structure 200 includes first metal lines 210 embedded in a first dielectric layer 214, second metal lines 242 embedded in a second dielectric layer 236, where the second metal lines 242 are arranged above the first metal lines 210, a top via 230 extending between one of the first metal lines (210) and one of the second metal lines (242), where the top via 230 is self-aligned to the one of the first metal lines (210), and at least one air gap 238 located adjacent to the top via 230 between the first metal lines 210 and the second metal lines 242, where the at least one air gap 238 is in the same level as the top via 230.

With continued reference to FIGS. 24-26, and according to an embodiment, the structure 200 includes first metal lines 210 embedded in a first dielectric layer 214, second metal lines 242 embedded in a second dielectric layer 236, where the second metal lines 242 are arranged above the first metal lines 210, a top via 230 extending between one of the first metal lines (210) and one of the second metal lines (242), where the top via 230 is self-aligned to the one of the first metal lines (210), and at least one air gap 238 located in the same level as the top via 230, where the at least one air gap 238 is arranged at intersections (see FIG. 26) between the first metal lines 210 and the second metal lines 242.

With continued reference to FIGS. 24-26, and according to an embodiment, the structure 200 includes first metal lines 210 embedded in a first dielectric layer 214, second metal lines 242 embedded in a second dielectric layer 236, where the second metal lines 242 are arranged above the first metal lines 210, a top via 230 extending between one of the first metal lines (210) and one of the second metal lines (242), where the top via 230 is self-aligned to the one of the first metal lines (210), dielectric plugs 218 located in the same level as the top via 230 and directly above all of the first metal lines 110 except where the top via 230 is positioned, and at least one air gap 238 located within at least one of the dielectric plugs 218 separating it from both the first dielectric layer 214 and the second dielectric layer 236.

With continued reference to FIGS. 24-26, and according to an embodiment, each of the dielectric plugs 218 is self-aligned with each of the first metal lines 210, respectively.

For reference purposes measurements taken in the x-direction, parallel to the first metal lines 110, 210, are herein referred to as “length”, while measurements taken in the y-direction, perpendicular to the first metal lines 110, 210 are herein referred to as “width”.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the invention. The terminology used herein was chosen to best explain the principles of the embodiment, the practical application or technical improvement over technologies found in the marketplace, or to enable others of ordinary skill in the art to understand the embodiments disclosed herein.

What is claimed is:

1. A semiconductor structure comprising:
first metal lines embedded in a first dielectric layer;
second metal lines embedded in a second dielectric layer, wherein the second metal lines are arranged above the first metal lines;
a top via extending between one of the first metal lines and one of the second metal lines, wherein the top via is self-aligned to the one of the first metal lines; and
at least one air gap located adjacent to the top via between the first metal lines and the second metal lines.

2. The semiconductor structure according to claim 1, further comprising:
a dielectric liner surrounding sides and a bottom of the at least one air gap.

3. The semiconductor structure according to claim 2, wherein the dielectric liner directly contacts all topmost surfaces of the first metal lines directly beneath the second metal lines except where the top via is positioned.

4. The semiconductor structure according to claim 1, further comprising:
masks (112) above and directly contacting topmost surfaces of the first metal lines except where the first metal lines are directly beneath the second metal lines, wherein bottom most surfaces of the masks are substantially flush with a bottom most surface of the top via.

5. The semiconductor structure according to claim 1, wherein a bottom most surface of the second metal lines is below a topmost surface of the first dielectric layer.

6. The semiconductor structure according to claim 1, wherein the first metal lines directly contact the first dielectric layer (114) without a barrier liner, wherein the top via directly contacts the first dielectric layer (114) without a barrier liner, and wherein the second metal lines directly contact both the first dielectric layer (114) and the second dielectric layer (118) without a barrier liner.

7. The semiconductor structure according to claim 1, wherein the first metal lines and the second metal lines comprise ruthenium.

8. A semiconductor structure comprising:
first metal lines embedded in a first dielectric layer;
second metal lines embedded in a second dielectric layer, wherein the second metal lines are arranged above the first metal lines;
a top via extending between one of the first metal lines and one of the second metal lines, wherein the top via is self-aligned to the one of the first metal lines; and
at least one air gap located adjacent to the top via between the first metal lines and the second metal lines, wherein the at least one air gap is in the same level as the top via.

9. The semiconductor structure according to claim 8, further comprising:
a dielectric liner surrounding sides and a bottom of the at least one air gap.

10. The semiconductor structure according to claim 9, wherein the dielectric liner directly contacts all topmost surfaces of the first metal lines directly beneath the second metal lines except where the top via is positioned.

11. The semiconductor structure according to claim 8, further comprising:
masks (112) above and directly contacting topmost surfaces of the first metal lines except where the first metal lines are directly beneath the second metal lines, wherein bottom most surfaces of the masks are substantially flush with a bottom most surface of the top via.

12. The semiconductor structure according to claim 8, wherein a bottom most surface of the second metal lines is below a topmost surface of the first dielectric layer.

13. The semiconductor structure according to claim 8, wherein the first metal lines directly contact the first dielectric layer without a barrier liner, wherein the top via directly contacts the first dielectric layer without a barrier liner, and wherein the second metal lines directly contact both the first dielectric layer and the second dielectric layer without a barrier liner.

14. The semiconductor structure according to claim 8, wherein the first metal lines and the second metal lines comprise ruthenium.

15. A semiconductor structure comprising:
first metal lines embedded in a first dielectric layer;
second metal lines embedded in a second dielectric layer, wherein the second metal lines are arranged above the first metal lines;
a top via extending between one of the first metal lines and one of the second metal lines, wherein the top via is self-aligned to the one of the first metal lines; and
at least one air gap located in the same level as the top via, wherein the at least one air gap is arranged at intersections between the first metal lines and the second metal lines.

16. The semiconductor structure according to claim 15, further comprising:
a dielectric liner surrounding sides and a bottom of the at least one air gap.

17. The semiconductor structure according to claim 16, wherein the dielectric liner directly contacts all topmost surfaces of the first metal lines directly beneath the second metal lines except where the top via is positioned.

18. The semiconductor structure according to claim 15, further comprising:
masks (112) above and directly contacting topmost surfaces of the first metal lines except where the first metal lines are directly beneath the second metal lines, wherein bottom most surfaces of the masks are substantially flush with a bottom most surface of the top via.

19. The semiconductor structure according to claim 15, wherein a bottom most surface of the second metal lines is below a topmost surface of the first dielectric layer.

20. The semiconductor structure according to claim 15, wherein the first metal lines directly contact the first dielectric layer without a barrier liner, wherein the top via directly contacts the first dielectric layer without a barrier liner, and wherein the second metal lines directly contact both the first dielectric layer and the second dielectric layer without a barrier liner.

21. The semiconductor structure according to claim 15, wherein the first metal lines and the second metal lines comprise ruthenium.

22. A semiconductor structure comprising:
first metal lines embedded in a first dielectric layer;
second metal lines embedded in a second dielectric layer, wherein the second metal lines are arranged above the first metal lines;
a top via extending between one of the first metal lines and one of the second metal lines, wherein the top via is self-aligned to the one of the first metal lines;
at least one air gap located in the same level as the top via, wherein the at least one air gap is arranged at intersections between the first metal lines and the second metal lines;
a dielectric liner surrounding sides and a bottom of the at least one air gap; and
masks (112) above and directly contacting topmost surfaces of the first metal lines except where the first metal lines are directly beneath the second metal lines, wherein bottom most surfaces of the masks are substantially flush with a bottom most surface of the top via.

23. The semiconductor structure according to claim 22, wherein the dielectric liner directly contacts all topmost surfaces of the first metal lines directly beneath the second metal lines except where the top via is positioned.

24. A semiconductor structure comprising:
first metal lines embedded in a first dielectric layer;
second metal lines embedded in a second dielectric layer, wherein the second metal lines are arranged above the first metal lines;
a top via extending between one of the first metal lines and one of the second metal lines, wherein the top via is self-aligned to the one of the first metal lines;
dielectric plugs located in the same level as the top via and directly above all of the first metal lines except where the top via is positioned; and
at least one air gap located within at least one of the dielectric plugs separating it from both the first dielectric layer and the second dielectric layer.

25. The semiconductor structure according to claim 24, wherein each of the dielectric plugs is self-aligned with each of the first metal lines, respectively.
